(19) United States
(12) Patent Application Publication
(10) Pub. No.: US 2023/0104836 A1
(43) Pub. Date: Apr. 6, 2023

(54) TRANSFER FILM AND METHOD FOR PRODUCING LAMINATE

(71) Applicant: FUJIFILM Corporation, Tokyo (JP)

(72) Inventors: Kunihiko KODAMA, Fujinomiya-shi (JP); Tatsuya SHIMOYAMA, Fujinomiya-shi (JP)

(73) Assignee: FUJIFILM Corporation, Tokyo (JP)

(21) Appl. No.: 18/061,211

(22) Filed: Dec. 2, 2022

Related U.S. Application Data
(63) Continuation of application No. PCT/JP2021/020833, filed on Jun. 1, 2021.

(30) Foreign Application Priority Data
Jun. 4, 2020 (JP) 2020-097537

(51) Int. Cl. G03F 7/033; C08F 265/06; G03F 7/20

(52) U.S. Cl. CPC G03F 7/033; C08F 265/06; G03F 7/2022

(57) ABSTRACT

An object of the present invention is to provide a transfer film with which a cured film having low moisture permeability and excellent bending resistance can be formed. In addition, an object of the present invention is to provide a method for producing a laminate using the transfer film. The transfer film of the present invention includes a temporary support and a photosensitive composition layer disposed on the temporary support, in which the photosensitive composition layer includes an alkali-soluble resin, a polymerizable compound, and a polymerization initiator represented by Formula I or Formula II, and a content of the polymerization initiator is 0.1% to 3.0% by mass with respect to a total mass of the photosensitive composition layer. X¹ is a group represented by —S—R¹¹ or a group represented by —R¹², R¹¹ and R¹² are each independently a monovalent organic group having 2 or more carbon atoms, X² is an n-valent linking group, Y¹, Y², Z¹, and Z² are alkyl groups or aryl groups, which may have a substituent, X³ is a monovalent substituent, m is an integer of 0 to 3, and n is 2 or 3.

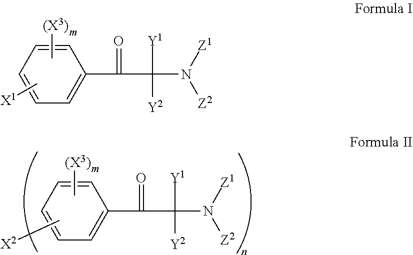

### CROSS-REFERENCE TO RELATED APPLICATIONS

This application is a Continuation of PCT International Application No. PCT/JP2021/020833 filed on Jun. 1, 2021, which claims priority under 35 U.S.C. § 119(a) to Japanese Patent Application No. 2020-097537 filed on Jun. 4, 2020. The above applications are hereby expressly incorporated by reference, in its entirety, into the present application.

### BACKGROUND OF THE INVENTION

### 1. Field of the Invention

The present invention relates to a transfer film and a method for producing a laminate.

### 2. Description of the Related Art

A photosensitive composition cured by irradiation with light is used for various purposes. For example, JP2016-90857A discloses that a composition including an α-aminoalkylphenone compound having a specific structure as a polymerization initiator, a curable resin, a diluent, and a filler is used for forming a solder resist.

### SUMMARY OF THE INVENTION

In recent years, from the viewpoint that the number of steps for obtaining a predetermined pattern is small, a method in which, using a transfer film, a photosensitive composition layer provided on any substrate is exposed through a mask and then developed has been widely used.

Here, the cured film obtained by exposing and developing the photosensitive composition layer may be used as a protective film (touch panel electrode protective film) for protecting a sensor electrode and a lead wire in a touch panel.

In a case where a transfer film having the photosensitive composition layer is produced using a photosensitive composition obtained with reference to the description of JP2016-90857A and a cured film is prepared by exposing and developing the photosensitive composition layer, the present inventors have found that there are cases where moisture permeability of the cured film may be high and bending resistance may be insufficient, so that there is room for improvement.

Therefore, an object of the present invention is to provide a transfer film with which a cured film having low moisture permeability and excellent bending resistance can be formed. Another object of the present invention is to provide a method for producing a laminate using the transfer film.

The present inventors have conducted intensive studies on the above-described objects, and as a result, have found that the above-described objects can be accomplished by the following configurations.

[1]

A transfer film comprising:

a temporary support; and

a photosensitive composition layer disposed on the temporary support,

in which the photosensitive composition layer includes an alkali-soluble resin, a polymerizable compound, and a polymerization initiator represented by Formula I described later or Formula II described later, and

a content of the polymerization initiator is 0.1% to 3.0% by mass with respect to a total mass of the photosensitive composition layer,

in Formula I described later, X¹ represents a group represented by —S—R¹¹ or a group represented by —R¹², R¹¹ and R¹² each independently represent a monovalent organic group having 2 or more carbon atoms,

in Formula II described later, X² represents an n-valent linking group,

in Formula I and Formula II described later, Y¹ and Y² each independently represent an alkyl group which may have a substituent or an aryl group which may have a substituent,

in Formula I and Formula II described later, Z¹ and Z² each independently represent an alkyl group which may have a substituent or an aryl group which may have a substituent, here, in a case where Z¹ and Z² are the alkyl group which may have a substituent, Z¹ and Z² may be linked to each other to form a ring,

in Formula I and Formula II described later, X³ represents a monovalent substituent,

in Formula I and Formula II described later, m represents an integer of 0 to 3, in a case where m is 2 or more, a plurality of X³'s may be the same or different from each other, and

in Formula II described later, n is 2 or 3.

[2]

The transfer film according to [1],

in which X¹ in Formula I described later is a group having an aromatic ring.

[3]

The transfer film according to [1] or [2],

in which the photosensitive composition layer further includes a polymerization initiator other than the polymerization initiator represented by Formula I and the polymerization initiator represented by Formula II.

[4]

The transfer film according to [3],

in which, in the photosensitive composition layer, a mass ratio of a total content of the polymerization initiator represented by Formula I and the polymerization initiator represented by Formula II to a content of the polymerization initiator other than the polymerization initiator represented by Formula I and the polymerization initiator represented by Formula II is 0.5 to 10.

[5]

The transfer film according to any one of [1] to [4],

in which the polymerizable compound includes a (meth)acrylate compound that has an aliphatic ring which may include an oxygen atom or a nitrogen atom in the ring and has two or more ethylenically unsaturated groups in one molecule.

[6]

The transfer film according to any one of [1] to [5],

in which the polymerizable compound includes a (meth)acrylate compound having two ethylenically unsaturated groups in one molecule and a (meth)acrylate compound having three to six ethylenically unsaturated groups in one molecule.

[7]

The transfer film according to any one of [1] to [6],

in which the alkali-soluble resin includes at least one structural unit of a structural unit having an aromatic ring or a structural unit having an aliphatic ring.

[8]

The transfer film according to any one of [1] to [7],

in which the alkali-soluble resin includes a structural unit having a radically polymerizable group.

[9]

The transfer film according to any one of [1] to [8],

in which the photosensitive composition layer further includes a blocked isocyanate compound.

[10]

The transfer film according to any one of [1] to [9], further comprising:

a refractive index-adjusting layer,

in which the refractive index-adjusting layer is disposed in contact with the photosensitive composition layer, and

a refractive index of the refractive index-adjusting layer is 1.60 or more.

[11]

The transfer film according to any one of [1] to [10],

in which the photosensitive composition layer is used for forming a touch panel electrode protective film.

[12]

A method for producing a laminate, comprising:

an affixing step of bringing the photosensitive composition layer on the temporary support of the transfer film according to any one of [1] to [11] into contact with a substrate having a conductive layer to affix the photosensitive composition layer to the substrate and obtain a photosensitive composition layer-attached substrate having the substrate, the conductive layer, the photosensitive composition layer, and the temporary support in this order;

an exposing step of exposing the photosensitive composition layer in a patterned manner; and

a developing step of developing the exposed photosensitive composition layer to form a pattern,

in which the producing method further includes, between the affixing step and the exposing step or between the exposing step and the developing step, a peeling step of peeling the temporary support from the substrate with a photosensitive composition layer.

According to the present invention, it is possible to provide a transfer film with which a cured film having low moisture permeability and excellent bending resistance can be formed. In addition, according to the present invention, it is possible to provide a method for producing a laminate using the transfer film.

### BRIEF DESCRIPTION OF THE DRAWINGS

FIG. 1 is a schematic cross-sectional view showing a state of a bending resistance evaluation sample in a bending resistance evaluation.

### DESCRIPTION OF THE PREFERRED EMBODIMENTS

Hereinafter, the details of the present invention will be described.

In the present specification, a numerical value range indicated by using “to” means a range including the numerical values before and after “to” as the lower limit value and the upper limit value, respectively.

In addition, regarding numerical ranges that are described stepwise in the present specification, an upper limit value or a lower limit value described in a numerical range may be replaced with an upper limit value or a lower limit value of another stepwise numerical range. In addition, in the range of numerical values described in the present specification, an upper limit value and a lower limit value disclosed in a certain range of numerical values may be replaced with values shown in Examples.

Further, a term “step” in the present specification indicates not only an independent step but also a step which cannot be clearly distinguished from other steps as long as the intended purpose of the step is achieved.

In the present specification, a term “transparent” means that an average transmittance of visible light at a wavelength of 400 to 700 nm is 80% or more, and preferably 90% or more.

In addition, the average transmittance of visible light is a value measured using a spectrophotometer, and can be measured, for example, using a spectrophotometer U-3310 manufactured by Hitachi, Ltd.

A weight-average molecular weight (Mw) and a number-average molecular weight (Mn) in the present disclosure are molecular weights in terms of polystyrene used as a standard substance, which are detected by using tetrahydrofuran (THF), a differential refractometer, and a gel permeation chromatography (GPC) analyzer using TSKgel GMHxL, TSKgel G4000HxL, and TSKgel G2000HxL (all product names manufactured by Tosoh Corporation) as columns, unless otherwise specified.

In the present disclosure, unless otherwise specified, a molecular weight of a compound having a molecular weight distribution is the weight-average molecular weight.

In addition, in the present specification, a refractive index is a value measured with an ellipsometer at a wavelength of 550 nm unless otherwise specified.

In the present specification, “(meth)acrylic” has a concept including both acrylic and methacrylic, “(meth)acrylate” has a concept including both acrylate and methacrylate, and “(meth)acryloxy group” has a concept including both acryloxy group and methacryloxy group.

[Transfer Film]

A transfer film according to an embodiment of the present invention has a temporary support and a photosensitive composition layer disposed on the temporary support, in which the photosensitive composition layer includes an alkali-soluble resin, a polymerizable compound, and a polymerization initiator (hereinafter, also referred to as a “specific polymerization initiator”) represented by Formula I or Formula II described later, and a content of the polymerization initiator is 0.1% to 3.0% by mass with respect to a total mass of the photosensitive composition layer.

Here, the details will be described later, but examples of a method for forming a cured film using the transfer film according to the embodiment of the present invention include a method in which a substrate having a conductive layer (sensor electrode, lead wire, and the like) or the like is brought into contact with the transfer film to affix the substrate to the transfer film, and through steps such as pattern exposure of the photosensitive composition layer having the transfer film, development, and post-baking, a cured film (a protective film in a patterned shape) is formed.

The cured film obtained as described above has low moisture permeability and is excellent in bending resistance. The details of the reason for this are not clear, but it is presumed that, as shown in the section of Examples described later, a content of the specific polymerization initiator in the photosensitive composition layer has an influence.

The transfer film according to the embodiment of the present invention can be applied to various applications. For example, the transfer film according to the embodiment of the present invention can be applied to an electrode protective film, an insulating film, a flattening film, an overcoat film, a hard coat film, a passivation film, a partition wall, a spacer, a microlens, an optical filter, an antireflection film, an etching resist, a plating member, or the like.

More specific examples thereof include a protective film or an insulating film for a touch panel electrode, a protective film or an insulating film for a printed wiring board, a protective film or an insulating film for a TFT substrate, a color filter, an overcoat film for a color filter, an etching resist for a wiring line formation, and a sacrificing layer during plating.

From the viewpoint of suppressing generation of air bubbles in the affixing step described later, the maximum width of undulation of the transfer film is preferably 300 μm or less, more preferably 200 μm or less, and still more preferably 60 μm or less. The lower limit value of the maximum width of undulation is 0 μm or more, preferably 0.1 μm or more and more preferably 1 μm or more.

The maximum width of undulation of the transfer film is a value measured by the following procedure.

First, the transfer film is cut in a direction perpendicular to the main surface so as to have a size of 20 cm in length×20 cm in width to produce a test sample. In a case where the transfer film has a protective film, the protective film is peeled off. Next, the above-described test sample is placed on a stage having a smooth and horizontal surface so that the surface of the temporary support faces the stage. After placing, for a range of 10 cm square in the center of the test sample, the surface of the test sample is scanned with a laser microscope (for example, VK-9700SP manufactured by Keyence Corporation) to obtain a three-dimensional surface image, and the minimum concave height is subtracted from the maximum convex height observed in the obtained three-dimensional surface image. The above-described operation is performed on 10 test samples, and the arithmetic mean value thereof is defined as the “maximum width of undulation of the transfer film”.

Hereinafter, each member constituting the transfer film will be described.

<Temporary Support>

The transfer film has a temporary support. The temporary support is a member which supports the photosensitive composition layer described later, and the like, and is finally removed by a peeling treatment.

The temporary support is preferably a film and more preferably a resin film. As the temporary support, a film which has flexibility and does not show significant deformation, contraction, or stretching under pressure or under pressure and heating can be used.

Examples of such a film include a polyethylene terephthalate film (for example, a biaxially stretching polyethylene terephthalate film), a cellulose triacetate film, a polystyrene film, a polyimide film, and a polycarbonate film.

Among these, as the temporary support, a biaxially stretching polyethylene terephthalate film is preferable.

In addition, it is preferable that the film used as the temporary support does not have deformations such as a wrinkles, a scratch, and the like.

From the viewpoint that pattern exposure through the temporary support can be performed, it is preferable that the temporary support has high transparency, and the transmittance at 365 nm is preferably 60% or more and more preferably 70% or more.

From the viewpoint of pattern forming properties during the pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of the pattern forming properties during the pattern exposure through the temporary support and the transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

A thickness of the temporary support is not particularly limited, but from the viewpoint of easiness of handling and general-purpose properties, is preferably 5 to 200 μm, more preferably 10 to 150 μm, and still more preferably 10 to 50 μm.

From the viewpoint of imparting handleability, a layer (lubricant layer) containing fine particles may be provided on a surface of the temporary support. The lubricant layer may be provided on one surface of the temporary support or on both surfaces thereof. A diameter of the particles contained in the lubricant layer may be 0.05 to 0.8 μm. In addition, a film thickness of the lubricant layer may be 0.05 to 1.0 μm.

Examples of the temporary support include a biaxially stretching polyethylene terephthalate film having a film thickness of 16 μm, a biaxially stretching polyethylene terephthalate film having a film thickness of 12 μm, and a biaxially stretching polyethylene terephthalate film having a film thickness of 9 μm.

For example, preferred aspects of the temporary support are described in paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

Examples of a commercially available product of the temporary support include LUMIRROR 16KS40 and LUMIRROR 16FB40 (all manufactured by Toray Industries, Inc.), and COSMOSHINE A4100, COSMOSHINE A4300, and COSMOSHINE A8300 (all manufactured by TOYOBO Co., Ltd.).

<Photosensitive Composition Layer>

The transfer film has a photosensitive composition layer. A pattern can be formed on an object to be transferred by transferring the photosensitive composition layer onto the object to be transferred and then exposing and developing the photosensitive composition layer.

The photosensitive composition layer includes an alkali-soluble resin, a polymerizable compound, and a specific polymerization initiator.

The photosensitive composition layer may be a positive tone or a negative tone.

The positive tone photosensitive composition layer is a photosensitive composition layer having a solubility in a developer that increases by exposure to an exposed portion, and the negative tone photosensitive composition layer is a photosensitive composition layer having a solubility in a developer that decreases by exposure to an exposed portion.

Among these, it is preferable to use a negative tone photosensitive composition layer. In a case where the photosensitive composition layer is a negative tone photosensitive composition layer, a pattern to be formed corresponds to a cured film.

Hereinafter, the components included in the negative tone photosensitive composition layer will be described in detail.

[Polymerizable Compound]

The photosensitive composition layer includes a polymerizable compound.

The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter, also simply referred to as an “ethylenically unsaturated compound”).

As the ethylenically unsaturated group, a (meth)acryloxy group is preferable.

The ethylenically unsaturated compound preferably includes a bi- or higher functional ethylenically unsaturated compound. Here, the “bi- or higher functional ethylenically unsaturated compound” means a compound having two or more ethylenically unsaturated groups in one molecule.

As the ethylenically unsaturated compound, a (meth)acrylate compound is preferable.

From the viewpoint of film hardness after curing, for example, the ethylenically unsaturated compound preferably includes a bifunctional ethylenically unsaturated compound (preferably a bifunctional (meth)acrylate compound) and a tri- or higher functional ethylenically unsaturated compound (preferably a tri- or higher functional (meth)acrylate compound).

Examples of the bifunctional ethylenically unsaturated compound include tricyclodecane dimethanol di(meth)acrylate, 1,9-nonanediol di(meth)acrylate, 1,10-decanediol di(meth)acrylate, and 1,6-hexanediol di(meth)acrylate.

Examples of a commercially available product of the bifunctional ethylenically unsaturated compound include tricyclodecane dimethanol diacrylate [product name: NK ESTER A-DCP, Shin-Nakamura Chemical Co., Ltd.], tricyclodecane dimethanol dimethacrylate [product name: NK ESTER DCP, Shin-Nakamura Chemical Co., Ltd.], 1,9-nonanediol diacrylate [product name: NK ESTER A-NOD-N, Shin-Nakamura Chemical Co., Ltd.], 1,10-decanediol diacrylate [product name: NK ESTER A-DOD-N, Shin-Nakamura Chemical Co., Ltd.], 1,6-hexanediol diacrylate [product name: NK ESTER A-HD-N, Shin-Nakamura Chemical Co., Ltd.], and dioxane glycol diacrylate (KAYARAD R-604 manufactured by Nippon Kayaku Co., Ltd.).

Examples of the tri- or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, isocyanuric acid tri(meth)acrylate, and glycerin tri(meth)acrylate.

Here, the “(tri/tetra/penta/hexa)(meth)acrylate” is a concept including tri(meth)acrylate, tetra(meth)acrylate, penta(meth)acrylate, and hexa(meth)acrylate. In addition, the “(tri/tetra)(meth)acrylate” is a concept including tri(meth)acrylate and tetra(meth)acrylate. The tri- or higher functional ethylenically unsaturated compound is not particularly limited in the upper limit of the number of functional groups, but the number of functional groups can be, for example, 20 or less, or can be 15 or less.

Examples of a commercially available product of the tri- or higher functional ethylenically unsaturated compound include dipentaerythritol hexaacrylate [product name: KAYARAD DPHA, Nippon Kayaku Co., Ltd.].

Examples of the ethylenically unsaturated compound also include a caprolactone-modified compound of a (meth)acrylate compound [KAYARAD (product name) DPCA-20 of Nippon Kayaku Co., Ltd., A-9300-1CL of Shin-Nakamura Chemical Co., Ltd., or the like], an alkylene oxide-modified compound of a (meth)acrylate compound [KAYARAD (product name) RP-1040 of Nippon Kayaku Co., Ltd., ATM-35E or A-9300 of Shin-Nakamura Chemical Co., Ltd., EBECRYL (product name) 135 of Daicel-Allnex Ltd., or the like], and ethoxylated glycerin triacrylate [NK ESTER A-GLY-9E of Shin-Nakamura Chemical Co., Ltd., or the like].

Examples of the ethylenically unsaturated compound also include a urethane (meth)acrylate compound. As the urethane (meth)acrylate compound, a tri- or higher functional urethane (meth)acrylate compound is preferable. Examples of the tri- or higher functional urethane (meth)acrylate compound include 8UX-015A [Taisei Fine Chemical Co., Ltd.], NK ESTER UA-32P [Shin-Nakamura Chemical Co., Ltd.], and NK ESTER UA-1100H [Shin-Nakamura Chemical Co., Ltd.].

From a viewpoint of improving developability, the ethylenically unsaturated compound preferably includes an ethylenically unsaturated compound having an acid group.

Examples of the acid group include a phosphoric acid group, a sulfonic acid group, and a carboxy group. Among these, as the acid group, a carboxy group is preferable.

Examples of the ethylenically unsaturated compound having an acid group include a tri- or tetrafunctional ethylenically unsaturated compound having an acid group [compound obtained by introducing a carboxy group to pentaerythritol tri- and tetraacrylate (PETA) skeletons (acid value: 80 to 120 mgKOH/g)], and a penta- or hexafunctional ethylenically unsaturated compound having an acid group [compound obtained by introducing a carboxy group to a dipentaerythritol penta- or hexaacrylate (DPHA) skeleton (acid value: 25 to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one compound selected from the group consisting of a bi- or higher functional ethylenically unsaturated compound having a carboxy group and a carboxylic acid anhydride thereof is preferable. In a case where the ethylenically unsaturated compound having an acid group is at least one compound selected from the group consisting of a bi- or higher functional ethylenically unsaturated compound having a carboxy group and a carboxylic acid anhydride thereof, the developability and the film hardness are further enhanced.

Examples of the bi- or higher functional ethylenically unsaturated compound having a carboxy group include ARONIX (product name) TO-2349 [Toagosei Co., Ltd.], ARONIX (product name) M-520 [Toagosei Co., Ltd.], and ARONIX (product name) M-510 [Toagosei Co., Ltd.].

As the ethylenically unsaturated compound having an acid group, polymerizable compounds having an acid group, which are described in paragraphs [0025] to [0030] of JP2004-239942A, can be preferably used, and the contents described in this publication are incorporated herein by reference.

A molecular weight of the ethylenically unsaturated compound is preferably 200 to 3,000, more preferably 250 to 2,600, still more preferably 280 to 2,200, and particularly preferably 300 to 2,200.

A content of the ethylenically unsaturated compound having a molecular weight of 300 or less among the ethylenically unsaturated compounds is preferably 30% by mass or less, more preferably 25% by mass or less, and still more preferably 20% by mass or less with respect to a content of all ethylenically unsaturated compounds included in the photosensitive composition layer.

The photosensitive composition layer may include only one kind of polymerizable compound, or may include two or more kinds of polymerizable compounds.

A content of the polymerizable compound (preferably, the ethylenically unsaturated compound) is preferably 1% to 70% by mass, more preferably 10% to 70% by mass, still more preferably 20% to 60% by mass, and particularly preferably 20% to 50% by mass with respect to the total mass of the photosensitive composition layer.

In a case where the photosensitive composition layer includes the bi- or higher functional ethylenically unsaturated compound, the photosensitive composition layer may further include a monofunctional ethylenically unsaturated compound.

In a case where the photosensitive composition layer includes the bi- or higher functional ethylenically unsaturated compound, it is preferable that the bi- or higher functional ethylenically unsaturated compound is a main component of ethylenically unsaturated compounds included in the photosensitive composition layer.

In a case where the photosensitive composition layer includes the bi- or higher functional ethylenically unsaturated compound, a content of the bi- or higher functional ethylenically unsaturated compound is preferably 60% to 100% by mass, more preferably 80% to 100% by mass, and still more preferably 90% to 100% by mass with respect to the content of all ethylenically unsaturated compounds included in the photosensitive composition layer.

In a case where the photosensitive composition layer includes the ethylenically unsaturated compound having an acid group (preferably, the bi- or higher functional ethylenically unsaturated compound having a carboxy group or the carboxylic acid anhydride thereof), the content of the ethylenically unsaturated compound having an acid group is preferably 1% to 50% by mass, more preferably 1% to 20% by mass, and still more preferably 1% to 10% by mass with respect to the total mass of the photosensitive composition layer.

Examples of one suitable aspect of the polymerizable compound include an aspect in which the polymerizable compound includes a (meth)acrylate compound (hereinafter, also referred to as a “bi- or higher functional (meth)acrylate compound having an aliphatic ring”) that has an aliphatic ring which may include an oxygen atom or a nitrogen atom in the ring and has two or more ethylenically unsaturated groups in one molecule. As a result, the effects of the present invention are more excellent.

From the viewpoint that the effects of the present invention are more excellent, the number of functional groups in the bi- or higher functional (meth)acrylate compound having an aliphatic ring is preferably 2 to 10, more preferably 2 to 5, still more preferably 2 or 3, and particularly preferably 2.

In the bi- or higher functional (meth)acrylate compound having an aliphatic ring, the aliphatic ring may include an oxygen atom or a nitrogen atom in the ring, but from the viewpoint that the effects of the present invention are more excellent, it is preferable that the aliphatic ring does not include an oxygen atom and a nitrogen atom in the ring.

From the viewpoint that the effects of the present invention are more excellent, the number of carbon atoms in the aliphatic ring is preferably 3 to 20, more preferably 5 to 15, and still more preferably 5 to 12.

Specific examples of the bi- or higher functional (meth)acrylate compound having an aliphatic ring include tricyclodecanedimethanol di(meth)acrylate and isocyanuric acid tri(meth)acrylate.

The polymerizable compound may include only one kind of bi- or higher functional (meth)acrylate compound having an aliphatic ring, or may include two or more kinds of bi- or higher functional (meth)acrylate compounds having an aliphatic ring.

In a case where the polymerizable compound includes the bi- or higher functional (meth)acrylate compound having an aliphatic ring, from the viewpoint that the effects of the present invention are more excellent, a content of the bi- or higher functional (meth)acrylate compound having an aliphatic ring is preferably 5% to 80% by mass, more preferably 10% to 70% by mass, and particularly preferably 20% to 60% by mass with respect to the total mass of the polymerizable compound in the photosensitive composition layer.

Examples of one suitable aspect of the polymerizable compound include an aspect in which the polymerizable compound includes a (meth)acrylate compound (hereinafter, also referred to as a “bifunctional (meth)acrylate compound”) having two ethylenically unsaturated groups in one molecule and a (meth)acrylate compound (hereinafter, also referred to as a “tri- to hexafunctional (meth)acrylate compound) having three to six ethylenically unsaturated groups in one molecule. As a result, at least one of bending resistance or reduction in moisture permeability is more excellent.

Examples of the bifunctional (meth)acrylate compound include the above-described bifunctional ethylenically unsaturated compound and bifunctional compounds of the above-described ethylenically unsaturated compound having an acid group.

Examples of the tri- to hexafunctional (meth)acrylate compound include the above-described tri- or higher functional ethylenically unsaturated compound and tri- to hexafunctional compounds of the above-described ethylenically unsaturated compound having an acid group.

The polymerizable compound may include only one kind of bifunctional (meth)acrylate compound, or may include two or more kinds of bifunctional (meth)acrylate compounds.

In addition, the polymerizable compound may include only one kind of tri- to hexafunctional (meth)acrylate compound, or may include two or more kinds of tri- to hexafunctional (meth)acrylate compounds.

In a case where the polymerizable compound includes the bifunctional (meth)acrylate compound and the tri- to hexafunctional (meth)acrylate compound, from the viewpoint that the effects of the present invention are more excellent, a content of the bifunctional (meth)acrylate compound is preferably 10% to 90% by mass, more preferably 20% to 80% by mass, and particularly preferably 30% to 70% by mass with respect to the total mass of the polymerizable compound in the photosensitive composition layer.

In a case where the polymerizable compound includes the bifunctional (meth)acrylate compound and the tri- to hexafunctional (meth)acrylate compound, from the viewpoint that the effects of the present invention are more excellent, a content of the tri- to hexafunctional (meth)acrylate compound is preferably 10% to 90% by mass, more preferably 20% to 80% by mass, and particularly preferably 30% to 70% by mass with respect to the total mass of the polymerizable compound in the photosensitive composition layer.

In a case where the polymerizable compound includes the bifunctional (meth)acrylate compound and the tri- to hexafunctional (meth)acrylate compound, from the viewpoint that the effects of the present invention are more excellent, a mass ratio (bifunctional (meth)acrylate compound/tri- to hexafunctional (meth)acrylate compound) of the content of the bifunctional (meth)acrylate compound to the content of the tri- to hexafunctional (meth)acrylate compound is preferably 1/9 to 9/1, more preferably 2/8 to 8/2, and still more preferably 3/7 to 7/3.

[Specific Polymerization Initiator]

The photosensitive composition layer includes the specific polymerization initiator which is a photopolymerization initiator. The specific polymerization initiator is a polymerization initiator represented by Formula I or Formula II.

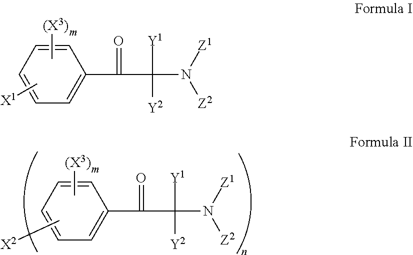

In Formula I, X¹ represents a group represented by —S—R¹¹ or a group represented by —R¹².

R¹¹ and R¹² each independently represent a monovalent organic group having 2 or more carbon atoms. The number of carbon atoms in the monovalent organic group in R¹¹ and R¹² is 2 or more, preferably 2 to 20, more preferably 3 to 15, and still more preferably 6 to 12.

Specific examples of the monovalent organic group in R¹¹ and R¹² include an alkyl group which may have a substituent and an aryl group which may have a substituent.

In the alkyl group in R¹¹ and R¹², which may have a substituent, the alkyl group may be linear, branched, or cyclic.

In the alkyl group in R¹¹ and R¹², which may have a substituent, examples of the substituent include an aryl group (preferably, a phenyl group), a hydroxyl group, a vinyl group, an alkoxy group (preferably, an alkoxy group having 1 to 3 carbon atoms), an alkoxycarbonyl group (that is, a group represented by R¹¹—O—C(O)—; R¹¹ represents an alkyl group, preferably an alkyl group having 1 to 3 carbon atoms), an acyloxy group (that is, a group represented by R¹²—C(O)O—; R¹² represents an alkyl group, preferably an alkyl group having 1 to 3 carbon atoms), a hydroxyalkyloxy group (group represented by HO—R¹³—O—; R¹³ represents an alkylene group, preferably an alkylene group having 1 to 4 carbon atoms), an amino group (examples thereof include —NH₂, —NR¹⁴, and —NR¹⁵R¹⁶; R¹⁴ to R¹⁶ each independently represent an alkyl group having 1 to 3 carbon atoms), an alkoxycarbonyloxy group (that is, a group represented by R¹⁷—O—C(O)—O; R¹⁷ represents an alkyl group, preferably an alkyl group having 1 to 5 carbon atoms), a group represented by C₆H₅—R¹⁸—O— (R¹⁸ represents an alkylene group, preferably an alkylene group having 1 to 4 carbon atoms), and a (meth)acryloyloxy group.

In the aryl group in R¹¹ and R¹², which may have a substituent, the aryl group may be a monocyclic ring or a fused ring, examples thereof include a phenyl group and a naphthyl group, and a phenyl group is preferable.

In the aryl group in R¹¹ and R¹², which may have a substituent, examples of the substituent include an alkyl group (preferably, an alkyl group having 1 to 5 carbon atoms), a hydroxyl group, a vinyl group, an alkoxy group (preferably, an alkoxy group having 1 to 3 carbon atoms), an alkoxycarbonyl group (that is, a group represented by R¹¹—O—C(O)—; R¹¹ represents an alkyl group, preferably an alkyl group having 1 to 3 carbon atoms), an acyloxy group (that is, a group represented by R¹²—C(O)O—; R¹² represents an alkyl group, preferably an alkyl group having 1 to 3 carbon atoms), a hydroxyalkyloxy group (group represented by HO—R¹³—O—; R¹³ represents an alkylene group, preferably an alkylene group having 1 to 4 carbon atoms), an amino group (examples thereof include —NH₂, —NR¹⁴, and —NR¹⁵R¹⁶; R¹⁴ to R¹⁶ each independently represent an alkyl group having 1 to 3 carbon atoms), an alkoxycarbonyloxy group (that is, a group represented by R¹⁷—O—C(O)—O; R¹⁷ represents an alkyl group, preferably an alkyl group having 1 to 5 carbon atoms), a group represented by C₆H₅—R¹⁸—O— (R¹⁸ represents an alkylene group, preferably an alkylene group having 1 to 4 carbon atoms), and a (meth)acryloyloxy group.

Among these, from the viewpoint that the effects of the present invention are more excellent, the group represented by —S—R¹¹ is preferably a group represented by the following formulae. In the formulae, * represents a bonding position with the benzene ring in Formula I.

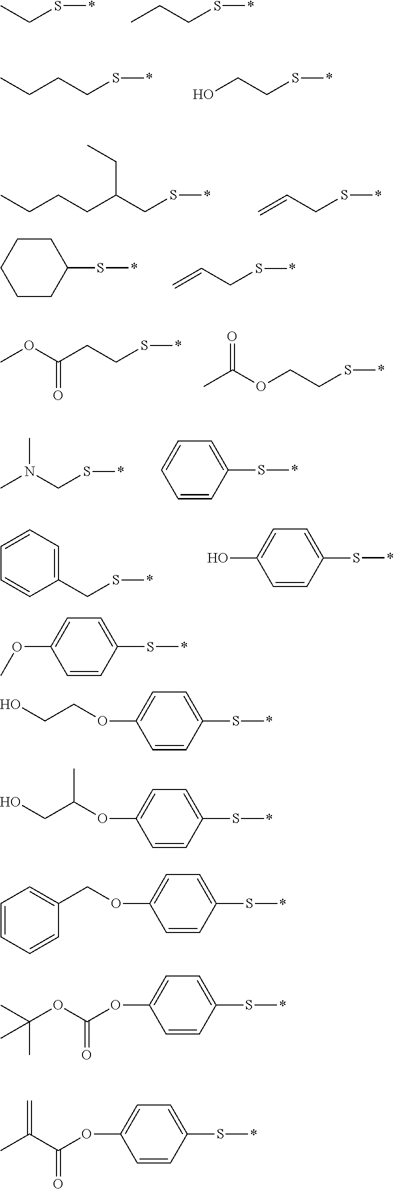

The group represented by —R¹² is preferably an aryl group which may have a substituent, more preferably an aryl group (that is, an aryl group which does not have a substituent), and still more preferably a phenyl group.

From the viewpoint that the effects of the present invention are more excellent, X¹ is preferably a group having an aromatic ring.

Examples of the group having an aromatic ring include a group that is the above-described alkyl group in R¹¹ and R¹², which may have a substituent, and the substituent is an aryl group (that is, an alkyl group substituted with an aryl group) and the above-described aryl group in R¹¹ and R¹², which may have a substituent.

Among the group represented by —S—R¹¹ and the group represented by —R¹², from the viewpoint that the effects of the present invention are more excellent, X¹ is preferably the group represented by —R¹².

In Formula II, X² represents an n-valent linking group. Examples of the n-valent linking group include a sulfur atom (—S—), an oxygen atom (—O—), a carbonyl group, a hydrocarbon group, and a group in which two or more of these groups or atoms are bonded.

Examples of the hydrocarbon group include an aliphatic hydrocarbon group and an aromatic hydrocarbon group.

The aliphatic hydrocarbon group may be saturated or unsaturated, but a saturated aliphatic hydrocarbon group is preferable and an alkylene group is more preferable. The alkylene group may be linear, branched, or cyclic, and is preferably linear. The number of carbon atoms in the aliphatic hydrocarbon group is preferably 1 to 10 and more preferably 2 to 8.

The aromatic hydrocarbon group may be a monocyclic ring or a fused ring, and may have a substituent. The aromatic hydrocarbon group is preferably a divalent aromatic hydrocarbon group and more preferably a phenylene group.

From the viewpoint that the effects of the present invention are more excellent, X² is preferably a group including a sulfur atom, and more preferably a divalent group including a sulfur atom, an alkylene group, and an oxygen atom, a divalent group including a sulfur atom, a phenylene group, an alkylene group, and an oxygen atom, a divalent group including a sulfur atom, a phenylene group, an alkylene group, an oxygen atom, and a carbonyl group, or a sulfur atom.

From the viewpoint that the effects of the present invention are more excellent, X² is preferably a divalent group represented by the following formulae. In the following formulae, * represents a bonding position with the benzene ring in Formula II.

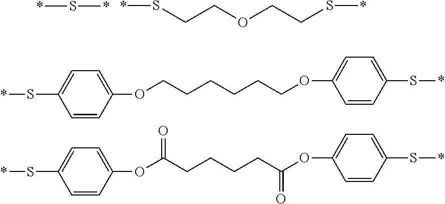

In Formula I and Formula II, Y¹ and Y² each independently represent an alkyl group which may have a substituent or an aryl group which may have a substituent.

In the alkyl group in Y¹ and Y², which may have a substituent, the alkyl group may be linear, branched, or cyclic, but is preferably linear. In addition, the number of carbon atoms in the alkyl group is preferably 1 to 5 and more preferably 1 to 3.

In the alkyl group in Y¹ and Y², which may have a substituent, specific examples of the substituent are the same as those in the specific examples of the substituent in the alkyl group in R¹¹ and R¹², which may have a substituent, and among those, a phenyl group is preferable.

In the aryl group in Yⁱ and Y², which may have a substituent, the aryl group may be a monocyclic ring or a fused ring, examples thereof include a phenyl group and a naphthyl group, and a phenyl group is preferable.

In the aryl group in Yⁱ and Y², which may have a substituent, the substituent are the same as those in the specific examples of the substituent in the aryl group in R¹¹ and R¹², which may have a substituent, and among those, an alkyl group is preferable.

From the viewpoint that the effects of the present invention are more excellent, Yⁱ and Y² are preferably a methyl group, an ethyl group, a benzyl group, or a p-tolylmethyl group.

In Formula I and Formula II, Z¹ and Z² each independently represent an alkyl group which may have a substituent or an aryl group which may have a substituent. However, in a case where Z¹ and Z² are the alkyl group which may have a substituent, Z¹ and Z² may be linked to each other to form a ring.

In the alkyl group in Z¹ and Z², which may have a substituent, the alkyl group may be linear, branched, or cyclic, but is preferably linear. In addition, the number of carbon atoms in the alkyl group is preferably 1 to 5 and more preferably 1 to 3.

In the alkyl group in Z¹ and Z², which may have a substituent, specific examples of the substituent are the same as those in the specific examples of the substituent in the alkyl group in R¹¹ and R¹², which may have a substituent.

In the aryl group in Z¹ and Z², which may have a substituent, the aryl group may be a monocyclic ring or a fused ring, examples thereof include a phenyl group and a naphthyl group, and a phenyl group is preferable.

In the aryl group in Z¹ and Z², which may have a substituent, the substituent are the same as those in the specific examples of the substituent in the aryl group in R¹¹ and R¹², which may have a substituent.

From the viewpoint that the effects of the present invention are more excellent, it is preferable that Z¹ and Z² are alkyl groups which may have a substituent, and it is more preferable that Z¹ and Z² are linked to each other to form a ring.

The ring formed by linking Z¹ and Z² to each other is a heterocyclic ring including a nitrogen atom in Formula I and Formula II, and may further include a heteroatom such as an oxygen atom, a sulfur atom, and a nitrogen atom in the ring. Among these, the ring formed by linking Z¹ and Z² to each other is preferably a morpholine ring or a piperidine ring and more preferably a morpholine ring.

In Formula I and Formula II, X³ represents a monovalent substituent. Specific examples of the monovalent substituent include a hydroxyl group, an amino group, a cyano group, a nitro group, an alkoxycarbonyl group, an acyloxy group, and the above-described groups represented by X¹ in Formula I.

In Formula I and Formula II, m represents an integer of 0 to 3, and is preferably 0 or 1 and more preferably 0.

In a case where m is 2 or more, a plurality of X³'s may be the same or different from each other.

In Formula II, n is 2 or 3, preferably 2.

Specific examples of the specific polymerization initiator are shown below, but the specific polymerization initiator is not limited thereto.

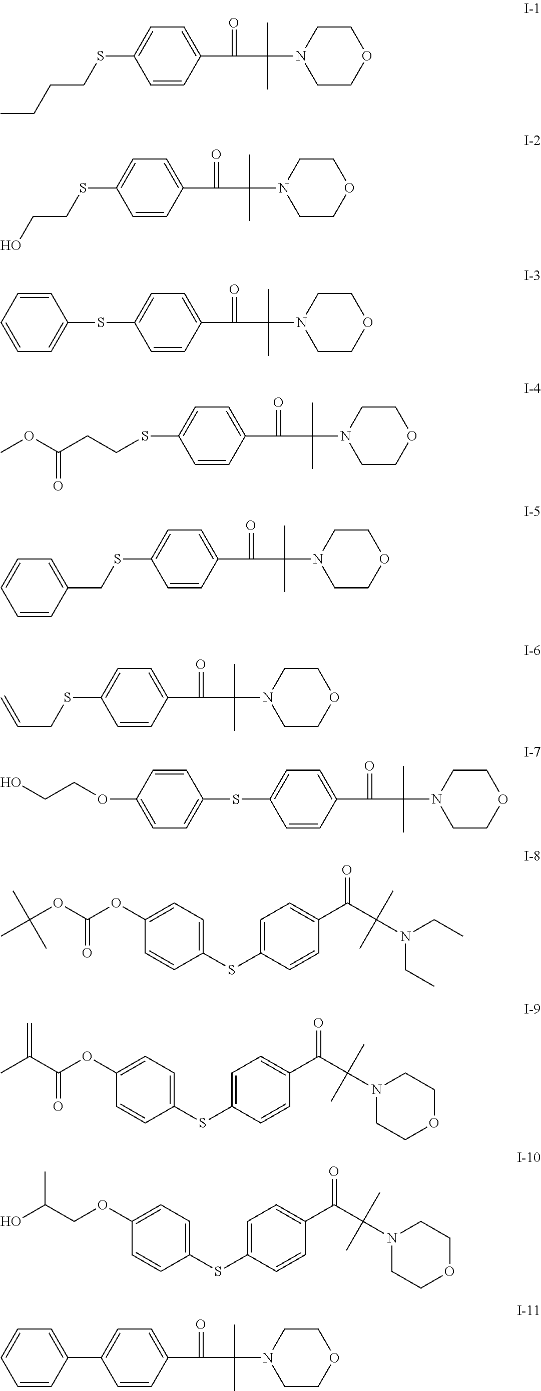

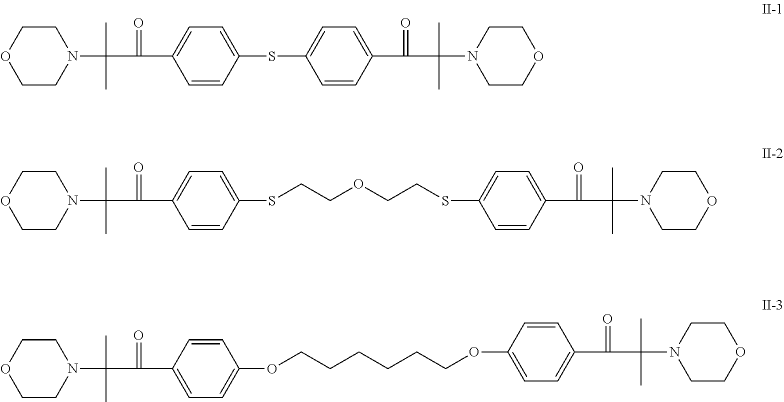 [SMILES: CC(C)(C(=O)c1ccc(Sc2ccc(C(=O)C(C)(C)N3CCOCC3)cc2)cc1)N1CCOCC1 ; CC(C)(C(=O)c1ccc(SCCOCCSc2ccc(C(=O)C(C)(C)N3CCOCC3)cc2)cc1)N1CCOCC1 ; CC(C)(C(=O)c1ccc(OCCCCCCOc2ccc(C(=O)C(C)(C)N3CCOCC3)cc2)cc1)N1CCOCC1]

From the viewpoint that the effects of the present invention are more excellent, the specific polymerization initiator is preferably the polymerization initiator represented by Formula I.

The photosensitive composition layer may include only one kind of specific polymerization initiator, or may include two or more kinds of specific polymerization initiators.

A content of the specific polymerization initiator is 0.1% to 3.0% by mass with respect to the total mass of the photosensitive composition layer.

From the viewpoint that adhesiveness to the conductive layer can be improved, the lower limit of the content of the specific polymerization initiator is preferably 0.2% by mass or more, and from the viewpoint the moisture permeability can be further reduced, more preferably 0.3% by mass or more.

From the viewpoint that adhesiveness to the conductive layer can be improved, the upper limit of the content of the specific polymerization initiator is preferably 2.0% by mass or less, from the viewpoint that yellowing of the cured film can be suppressed, more preferably 1.5% by mass or less, and from the viewpoint that the bending resistance is more excellent, still more preferably 1.0% by mass or less.

The specific polymerization initiator may include impurities derived from a synthesis process thereof, a raw material, or the like. Examples of the impurities include an unreacted raw material, a catalyst, a metal ion, and a halogen ion. From the viewpoint of exhibiting stable performance, it is preferable that a content of the impurities is small. Specifically, based on the mass of the specific polymerization initiator, the content of the impurities is preferably less than 1000 ppm by mass, more preferably less than 100 ppm by mass, still more preferably less than 10 ppm by mass, and particularly preferably less than 1 ppm by mass.

[Other Polymerization Initiators]

The photosensitive composition layer may include a polymerization initiator other than the above-described specific polymerization initiator (hereinafter, also referred to as “other polymerization initiators”). As the other polymerization initiator, a photopolymerization initiator is preferable.

Examples of the photopolymerization initiator include a photopolymerization initiator having an oxime ester structure (hereinafter also referred to as an “oxime-based photopolymerization initiator”), a photopolymerization initiator having an α-aminoalkylphenone structure (hereinafter also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure (hereinafter also referred to as an “acylphosphine oxide-based photopolymerization initiator”), and a photopolymerization initiator having an N-phenylglycine structure (hereinafter also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs [0031] to [0042] of JP2011-095716A and paragraphs [0064] to [0081] of JP2015-014783A may be used.

Examples of a commercially available product of the photopolymerization initiator include 1-[4-(phenylthio)]phenyl-1,2-octanedione-2-(O-benzoyloxime) [product name: IRGACURE (product name) OXE-01, manufactured by BASF SE], 1-[9-ethyl-6-(2-methylbenzoyl)-9H-carbazol-3-yl]ethanone-1-(0-acetyloxime) [product name: IRGACURE (product name) OXE-02, manufactured by BASF SE], 8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (product name) OXE-03, manufactured by BASF SE], 1-[4-[4-(2-benzofuranylcarbonyl)phenyl]thio]phenyl]-4-methyl-1-pentanone-1-(O-acetyloxime) [product name: IRGACURE (product name) OXE-04, manufactured by BASF SE], 2-(dimethylamino)-2-[(4-methylphenyl)methyl]-1-[4-(4-morpholinyl)phenyl]-1-butanone [product name: IRGACURE (product name) 379EG, manufactured by BASF SE], 2-methyl-1-(4-methylthiophenyl)-2-morpholinopropan-1-one [product name: Omnirad 907, manufactured by IGM Resins B. V.], 2-hydroxy-1-{4-[4-(2-hydroxy-2-methyl-propionyl)benzyl]phenyl}-2-methylpropan-1-one [product name: IRGACURE (product name) 127, manufactured by BASF SE], 2-benzyl-2-dimethylamino-1-(4-morpholinophenyl)-butanone-1 [product name: IRGACURE (product name) 369, manufactured by BASF SE], 2-hydroxy-2-methyl-1-phenyl-propan-1-one [product name: IRGACURE (product name) 1173, manufactured by BASF SE], 1-hydroxy cyclohexyl phenyl ketone [product name: IRGACURE (product name) 184, manufactured by BASF SE], 2,2-dimethoxy-1,2-diphenylethan-1-one (product name: IRGACURE 651, manufactured by BASF SE], an oxime ester-based compound [product name: Lunar (product name) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY).

The photosensitive composition layer may include only one kind of other polymerization initiator, or may include two or more kinds of other polymerization initiators.

From the viewpoint that the effects of the present invention are more excellent, it is preferable that the photosensitive composition layer includes the specific polymerization initiator and the other polymerization initiators.

In a case where the photosensitive composition layer includes the other polymerization initiators, from the viewpoint that the effects of the present invention are more excellent, a mass ratio (content of the specific polymerization initiator/content of the other polymerization initiators) of the content of the specific polymerization initiator to a content of the other polymerization initiators is preferably 0.5 or more, more preferably 0.8 or more, and still more preferably 1.5 or more; and preferably 10 or less, more preferably 6 or less, still more preferably 5 or less, and particularly preferably 3 or less.

In a case where the photosensitive composition layer includes the other polymerization initiators, the content of the other polymerization initiators is preferably 0.1% by mass or more, and more preferably 0.3% by mass or more with respect to the total mass of the photosensitive composition layer. In addition, the upper limit of the content of the other polymerization initiators is preferably 10% by mass or less, more preferably 5% by mass or less, still more preferably 3% by mass or less, and particularly preferably 1% by mass or less with respect to the total mass of the photosensitive composition layer.

[Alkali-Soluble Resin]

The photosensitive composition layer includes an alkali-soluble resin. Since the photosensitive composition layer includes the alkali-soluble resin, the solubility of the photosensitive composition layer (non-exposed portion) in a developer is improved.

In the present disclosure, “alkali-soluble” means that a dissolution rate obtained by the following method is 0.01 μm/sec or more.

A propylene glycol monomethyl ether acetate solution in which a concentration of a target compound (for example, a resin) is 25% by mass is applied to a glass substrate, and then heated in an oven at 100° C. for 3 minutes to form a coating film (thickness of 2.0 μm) of the target compound. The above-described coating film is immersed in a 1% by mass aqueous solution of sodium carbonate (liquid temperature of 30° C.), thereby obtaining the dissolution rate (m/sec) of the above-described coating film.

In a case where the target compound is not dissolved in propylene glycol monomethyl ether acetate, the target compound is dissolved in an organic solvent other than propylene glycol monomethyl ether acetate (for example, tetrahydrofuran, toluene, or ethanol), which has a boiling point of lower than 200° C.

It is preferable that the alkali-soluble resin includes at least one selected from a structural unit having an aromatic ring and a structural unit having an aliphatic ring, and a structural unit having an acid group, and it is more preferable that the alkali-soluble resin further includes a structural unit having a radically polymerizable group.

(Structural Unit Having Aromatic Ring)

The alkali-soluble resin preferably includes a structural unit having an aromatic ring. As the structural unit having an aromatic ring, a (meth)acrylate structural unit having an aromatic ring in the side chain or a structural unit derived from a vinylbenzene derivative (hereinafter, also referred to as a “vinylbenzene derivative unit”) is preferable.

Examples of a monomer for forming the (meth)acrylate structural unit having an aromatic ring in the side chain include benzyl (meth)acrylate, phenethyl (meth)acrylate, and phenoxyethyl (meth)acrylate.

As the vinylbenzene derivative unit, a unit represented by Formula (1) (hereinafter, also referred to as a “unit (1)”) is preferable.

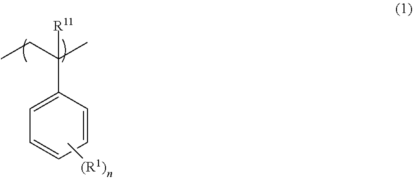

In Formula (1), n represents an integer of 0 to 5. In Formula (1), R¹ represents a substituent. In a case where n is 2 or more, two R¹'s may be bonded to each other to form a fused-ring structure. In a case where n is 2 or more, R¹'s may be the same or different from each other.

As the substituent represented by R¹, a halogen atom, an alkyl group, an aryl group, an alkoxy group, or a hydroxyl group is preferable.

As the halogen atom which is one of the preferred aspects of R¹, a fluorine atom, a chlorine atom, a bromine atom, or an iodine atom is preferable, and a fluorine atom, a chlorine atom, or a bromine atom is more preferable.

The number of carbon atoms in the alkyl group which is one of the preferred aspects of R¹ is preferably 1 to 20, more preferably 1 to 12, still more preferably 1 to 6, even more preferably 1 to 3, particularly preferably 1 or 2, and most preferably 1.

The number of carbon atoms in the aryl group which is one of the preferred aspects of R¹ is preferably 6 to 20, more preferably 6 to 12, still more preferably 6 to 10, and particularly preferably 6.

The number of carbon atoms in the alkoxy group which is one of the preferred aspects of R¹ is preferably 1 to 20, more preferably 1 to 12, still more preferably 1 to 6, even more preferably 1 to 3, particularly preferably 1 or 2, and most preferably 1.

R¹¹ represents a hydrogen atom or a methyl group.

In Formula (1), as n, an integer of 0 to 2 is particularly preferable.

In Formula (1), as the fused-ring structure which can be formed by bonding two R's to each other in a case where n is 2, a naphthalene ring structure or an anthracene ring structure is preferable.

Examples of a monomer for forming the vinylbenzene derivative unit include styrene, 1-vinylnaphthalene, 2-vinylnaphthalene, vinylbiphenyl, vinylanthracene, 4-hydroxystyrene, 4-bromostyrene, 4-methoxystyrene, 4-tert-butyl styrene, and α-methylstyrene, and styrene is particularly preferable.

As the structural unit having an aromatic ring, a structural unit formed of styrene is most preferable.

In a case where the alkali-soluble resin includes the structural unit having an aromatic ring, from the viewpoint that a corrosion of a wiring line and an electrode can be suppressed, a content of the structural unit having an aromatic ring is preferably 25% by mass or more, more preferably 35% by mass or more, and still more preferably 45% by mass or more with respect to the total amount of all structural units included in the alkali-soluble resin.

The upper limit value of the content of the structural unit having an aromatic ring is preferably 80% by mass or less, more preferably 70% by mass or less, and still more preferably 60% by mass or less.

The alkali-soluble resin may include only one kind of structural unit having an aromatic ring, or may include two or more kinds of structural units having an aromatic ring.

In the present disclosure, in a case where the content of “structural unit” is specified in % by mass, the “structural unit” is synonymous with “monomer unit” unless otherwise specified. In addition, in the present disclosure, in a case where a resin or polymer has two or more specific structural units, the content of the specific structural units indicates the total content of the two or more specific structural units unless otherwise specified.

(Structural Unit Having Aliphatic Ring)

Examples of the structural unit having an aliphatic ring include a structural unit formed by using an alkyl (meth)acrylate having a cyclic aliphatic hydrocarbon group. The cyclic aliphatic hydrocarbon group may be monocyclic or polycyclic.

Examples of the alkyl (meth)acrylate having a cyclic aliphatic hydrocarbon group include dicyclopentanyl (meth)acrylate, dicyclopentenyl (meth)acrylate, dicyclopentenyloxyethyl (meth)acrylate, cyclohexyl (meth)acrylate, cyclopentyl (meth)acrylate, isobornyl (meth)acrylate, and 1-adamantyl (meth)acrylate.

In a case where the alkali-soluble resin includes the structural unit having an aliphatic ring, from the viewpoint that a corrosion of a wiring line and an electrode can be suppressed, a content of the structural unit having an aliphatic ring is preferably 5% by mass or more, more preferably 10% by mass or more, and still more preferably 20% by mass or more with respect to the total amount of all structural units included in the alkali-soluble resin.

The upper limit value of the content of the structural unit having an aliphatic ring is preferably 80% by mass or less, more preferably 70% by mass or less, and still more preferably 60% by mass or less.

(Structural Unit Having Acid Group)

The alkali-soluble resin preferably includes a structural unit having an acid group (hereinafter, also referred to as an “acid group-containing unit”).

In a case where the alkali-soluble resin includes the acid group-containing unit, the photosensitive composition layer has alkali-soluble property.

Examples of the acid group in the acid group-containing unit include a carboxy group, a sulfonic acid group, a sulfate group, and a phosphoric acid group, and a carboxy group is preferable.

As the acid group-containing unit, a unit represented by Formula (3) (hereinafter, also referred to as a “unit (3)”) is preferable.

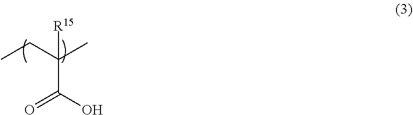

In Formula (3), R⁵ represents a hydrogen atom or an alkyl group.

The number of carbon atoms in the alkyl group represented by R⁵ is preferably 1 to 3, more preferably 1 or 2, and still more preferably 1.

As R⁵, a hydrogen atom or an alkyl group having 1 to 3 carbon atoms is preferable, a hydrogen atom, a methyl group, or an ethyl group is more preferable, and a hydrogen atom or a methyl group is still more preferable.

A monomer for forming the acid group-containing unit, (meth)acrylic acid is particularly preferable.

In a case where the alkali-soluble resin includes the acid group-containing unit, from the viewpoint that a corrosion of a wiring line and an electrode can be suppressed, a content of the acid group-containing unit is preferably 10% to 40% by mass, more preferably 15% to 30% by mass, and still more preferably 15% to 25% by mass with respect to the total amount of all structural units included in the alkali-soluble resin.

The alkali-soluble resin may include only one kind of acid group-containing unit, or may include two or more kinds of acid group-containing units.

(Structural Unit Having Radically Polymerizable Group)

The alkali-soluble resin preferably includes a structural unit having a radically polymerizable group (hereinafter, also referred to as a “radically polymerizable group-containing unit”). As a result, the moisture permeability can be further reduced.

In the radically polymerizable group-containing unit, as the radically polymerizable group, a group having an ethylenic double bond (hereinafter, also referred to as an “ethylenically unsaturated group”) is preferable, and a (meth)acryloyl group is more preferable.

As the radically polymerizable group-containing unit, a unit represented by Formula (2) (hereinafter, also referred to as a “unit (2)”) is preferable.

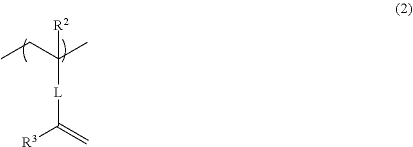

In Formula (2), R² and R³ each independently represent a hydrogen atom or an alkyl group, and L represents a divalent linking group.

The number of carbon atoms in the alkyl group represented by each of R² and R³ is preferably 1 to 3, more preferably 1 or 2, and still more preferably 1.

As the divalent linking group represented by L, one group selected from the group consisting of a carbonyl group (that is, a —C(═O)— group), an oxygen atom (that is, a —O— group), an alkylene group, and an arylene group or a group formed by linking two or more groups selected from the group is preferable.

Each of the alkylene group and the arylene group may be substituted with a substituent (for example, a hydroxyl group other than a primary hydroxyl group, a halogen atom, or the like).

The divalent linking group represented by L may have a branched structure.

The number of carbon atoms in the divalent linking group represented by Lis preferably 1 to 30, more preferably 1 to 20, and still more preferably 2 to 10.

As the divalent linking group represented by L, the following groups are particularly preferable.

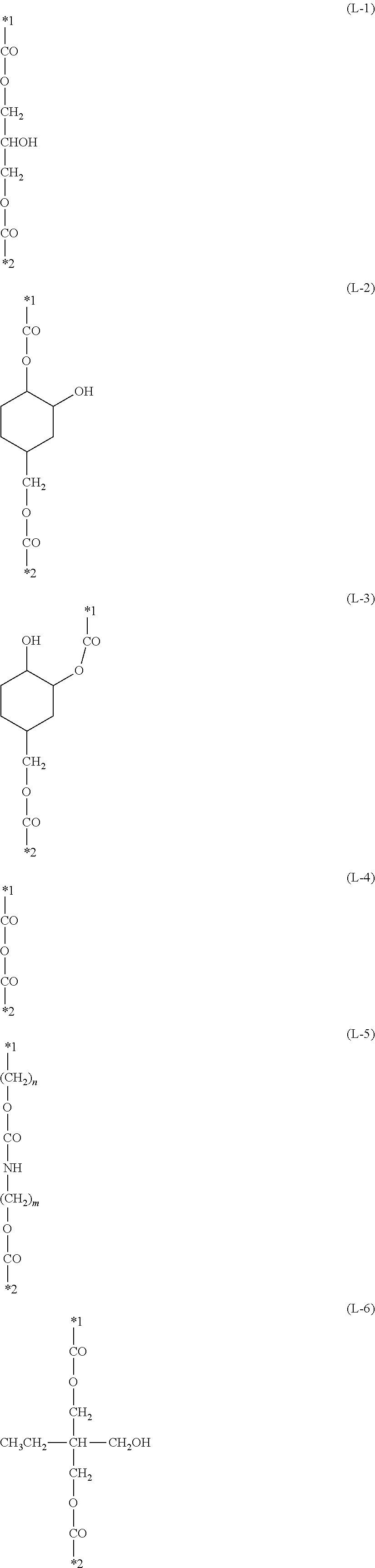

In each of the above groups, *1 represents a bonding position with a carbon atom included in the main chain of Formula (2), and *2 represents a bonding position with a carbon atom forming a double bond in Formula (2).

In addition, in (L-5), n and m each independently represent an integer of 1 to 6.

Examples of the radically polymerizable group-containing unit include a structural unit in which an epoxy group-containing monomer is added to a (meth)acrylic acid unit and a structural unit in which an isocyanate group-containing monomer is added to a hydroxyl group-containing monomer unit.

As the epoxy group-containing monomer, an epoxy group-containing (meth)acrylate having total carbon atoms of 5 to 24 is preferable, an epoxy group-containing (meth)acrylate having total carbon atoms of 5 to 12 is more preferable, and glycidyl (meth)acrylate or 3,4-epoxycyclohexylmethyl (meth)acrylate is still more preferable.

As a hydroxyl group-containing monomer for forming the hydroxyl group-containing monomer unit, a hydroxyalkyl (meth)acrylate having total carbon atoms of 4 to 24 is preferable, a hydroxyalkyl (meth)acrylate having total carbon atoms of 4 to 12 is more preferable, and hydroxyethyl (meth)acrylate is still more preferable.

Here, the “(meth)acrylic acid unit” means a structural unit derived from (meth)acrylic acid.

Similarly, in the present specification, a term “unit” added immediately after the monomer name (for example, “hydroxyl group-containing monomer unit”) means a structural unit derived from the monomer (for example, the hydroxyl group-containing monomer).

More specific examples of the radically polymerizable group-containing unit include
a structural unit in which glycidyl (meth)acrylate is added to a (meth)acrylic acid unit,
a structural unit in which (meth)acrylic acid is added to a (meth)acrylic acid unit,
a structural unit in which 3,4-epoxycyclohexylmethyl (meth)acrylate is added to a (meth)acrylic acid unit,
a structural unit in which 2-isocyanatoethyl (meth)acrylate is added to a hydroxyethyl (meth)acrylate unit,
a structural unit in which 2-isocyanatoethyl (meth)acrylate is added to a hydroxybutyl (meth)acrylate unit, and
a structural unit in which 2-isocyanatoethyl (meth)acrylate is added to a hydroxystyrene unit.

As the radically polymerizable group-containing unit,
a structural unit in which glycidyl (meth)acrylate is added to a (meth)acrylic acid unit or a structural unit in which 3,4-epoxycyclohexylmethyl (meth)acrylate is added to a (meth)acrylic acid unit is still more preferable; and
a structural unit in which glycidyl methacrylate is added to a methacrylic acid unit or a structural unit in which 3,4-epoxycyclohexylmethyl methacrylate is added to a methacrylic acid unit is particularly preferable.

In a case where the alkali-soluble resin includes the radically polymerizable group-containing unit, from the viewpoint that a corrosion of a wiring line and an electrode can be suppressed, a content of the radically polymerizable group-containing unit is preferably 10% to 60% by mass, more preferably 20% to 50% by mass, and still more preferably 25% to 40% by mass with respect to the total amount of all structural units included in the alkali-soluble resin.

The alkali-soluble resin may include only one kind of radically polymerizable group-containing unit, or may include two or more kinds of radically polymerizable group-containing units.

(Other Structural Units)

The alkali-soluble resin may include a structural unit other than the structural units described above.

Examples of other structural units include an alkyl (meth)acrylate structural unit which has a hydroxyl group and does not have a radically polymerizable group and an acid group and an alkyl (meth)acrylate structural unit which does not have a hydroxyl group, a radically polymerizable group, and an acid group.

Examples of a monomer for forming the alkyl (meth)acrylate structural unit which has a hydroxyl group and does not have a radically polymerizable group and an acid group include hydroxyethyl (meth)acrylate and 4-hydroxybutyl (meth)acrylate.

Examples of a monomer forming the alkyl (meth)acrylate structural unit which does not have a hydroxyl group, a radically polymerizable group, and an acid group include an alkyl (meth)acrylate having a linear or branched aliphatic hydrocarbon group (for example, methyl (meth)acrylate, butyl (meth)acrylate, and the like).

A content of the alkyl (meth)acrylate structural unit which has a hydroxyl group and does not have a radically polymerizable group and an acid group is preferably 0% to 10% by mass and more preferably 1% to 5% by mass with respect to the total amount of all structural units included in the alkali-soluble resin.

A content of the alkyl (meth)acrylate structural unit which does not have a hydroxyl group, a radically polymerizable group, and an acid group is preferably 0% to 30% by mass and more preferably 1% to 5% by mass with respect to the total amount of all structural units included in the alkali-soluble resin.

The alkali-soluble resin may include only one kind of other structural units, or may include two or more kinds of other structural units.

A weight-average molecular weight (Mw) of the alkali-soluble resin is preferably 5,000 or more, more preferably 5,000 to 100,000, still more preferably 7,000 to 50,000, and particularly preferably 10000 to 30000.

From the viewpoint of development residue reduction, a dispersity (weight-average molecular weight Mw/number-average molecular weight Mn) of the alkali-soluble resin is preferably 1.0 to 3.0 and more preferably 1.8 to 2.8.

From the viewpoint of developability, an acid value of the alkali-soluble resin is preferably 50 mgKOH/g or more, more preferably 60 mgKOH/g or more, still more preferably 70 mgKOH/g or more, and particularly preferably 80 mgKOH/g or more.

From the viewpoint of suppressing dissolution in a developer, the upper limit of the acid value of the alkali-soluble resin is preferably 200 mgKOH/g or less, more preferably 150 mgKOH/g or less, and still more preferably 130 mgKOH/g or less.

As the acid value, a value of the theoretical acid value calculated by the calculation method described in paragraph [0063] of JP2004-149806A, paragraph [0070] of JP2012-211228A, or the like can be used.

The photosensitive composition layer may include only one kind of alkali-soluble resin, or may include two or more kinds of alkali-soluble resins.

From the viewpoint of developability, a content of the alkali-soluble resin is preferably 10% to 90% by mass, more preferably 20% to 80% by mass, and still more preferably 25% to 70% by mass with respect to the total mass of the photosensitive composition layer.

Examples of one suitable aspect of the alkali-soluble resin include an aspect in which the alkali-soluble resin includes at least one structural unit of the above-described structural unit having an aromatic ring or the above-described structural unit having an aliphatic ring. As a result, the moisture permeability can be further lowered.

Among the structural unit having an aromatic ring and the structural unit having an aliphatic ring, an aspect of including the structural unit having an aromatic ring is preferable, an aspect of including the vinylbenzene derivative unit is more preferable, and an aspect of including the structural unit formed of styrene is still more preferable.

[Blocked Isocyanate Compound]

It is preferable that the photosensitive composition layer includes a blocked isocyanate compound. The blocked isocyanate compound contributes to improvement of hardness of a pattern to be formed.

Since the blocked isocyanate compound reacts with a hydroxyl group and a carboxy group, for example, in a case where at least one of the binder polymer or the radically polymerizable compound having an ethylenically unsaturated group has at least one of a hydroxyl group or a carboxy group, hydrophilicity of the formed film tends to decrease, and the function as a protective film tends to be strengthened. The blocked isocyanate compound refers to a “compound having a structure in which the isocyanate group of isocyanate is protected (so-called masked) with a blocking agent”.

In a case where the photosensitive composition layer includes the blocked isocyanate compound, from the viewpoint that the effects of the present invention are more excellent, a content of the blocked isocyanate compound is preferably 1% to 40% by mass, more preferably 5% to 30% by mass, and still more preferably 10% to 20% by mass with respect to the total mass of the photosensitive composition layer.

The photosensitive composition layer may include only one kind of blocked isocyanate compound, or may include two or more kinds of blocked isocyanate compounds.

(First Blocked Isocyanate Compound)

It is preferable that the blocked isocyanate compound includes a blocked isocyanate compound having a blocked isocyanate equivalent (hereinafter, also referred to as an “NCO value”) of 4.5 mmol/g or more (hereinafter, also referred to as a “first blocked isocyanate compound”). As a result, the bending resistance is more excellent, and the corrosion of the conductive layer can be suppressed.

From the viewpoint that the effects of the present invention are more excellent, an NCO value of the first blocked isocyanate compound is 4.5 mmol/g or more, preferably 5.0 mmol/g or more and more preferably 5.3 mmol/g or more.

From the viewpoint that the effects of the present invention are more excellent, the upper limit value of the NCO value of the first blocked isocyanate compound is preferably 6.0 mmol/g or less, more preferably less than 5.8 mmol/g, and still more preferably 5.7 mmol/g or less.

The NCO value of the blocked isocyanate compound in the present invention means the number of millimoles of blocked isocyanate groups included in 1 g of the blocked isocyanate compound, and can be calculated by the following expression.

NCO value of blocked isocyanate compound=1000×(Number of blocked isocyanate groups included in molecule)/(Molecular weight of blocked isocyanate compound)

A dissociation temperature of the first blocked isocyanate compound is preferably 100° C. to 160° C., and more preferably 110° C. to 150° C.

In the present specification, the “dissociation temperature of the blocked isocyanate compound” means a temperature at an endothermic peak accompanied with a deprotection reaction of the blocked isocyanate compound, in a case where the measurement is performed by differential scanning calorimetry (DSC) analysis using a differential scanning calorimeter. As the differential scanning calorimeter, for example, a differential scanning calorimeter (model: DSC6200) manufactured by Seiko Instruments Inc. can be suitably used. It should be noted that the differential scanning calorimeter is not limited to the differential scanning calorimeter described above.

Examples of the blocking agent having a dissociation temperature of 100° C. to 160° C. include active methylene compounds [diester malonates (such as dimethyl malonate, diethyl malonate, di-n-butyl malonate, and di-2-ethylhexyl malonate)], and oxime compounds (compound having a structure represented by —C(═N—OH)— in a molecule, such as formaldoxime, acetoaldoxime, acetoxime, methyl ethyl ketoxime, and cyclohexanone oxime). Among these, from the viewpoint of storage stability, an oxime compound is preferable as the blocking agent having a dissociation temperature of 100° C. to 160° C.

From the viewpoint that the effects of the present invention are more excellent, the first blocked isocyanate compound preferably has a ring structure. Examples of the ring structure include an aliphatic hydrocarbon ring, an aromatic hydrocarbon ring, and a heterocyclic ring, and from the viewpoint that the effects of the present invention are more excellent, an aliphatic hydrocarbon ring or an aromatic hydrocarbon ring is preferable, and an aliphatic hydrocarbon ring is more preferable.

Specific examples of the aliphatic hydrocarbon ring include a cyclopentane ring and a cyclohexane ring, and among these, a cyclohexane ring is preferable.

Specific examples of the aromatic hydrocarbon ring include a benzene ring and a naphthalene ring, and among these, a benzene ring is preferable.

Specific examples of the heterocyclic ring include an isocyanurate ring.

In a case where the first blocked isocyanate compound has a ring structure, from the viewpoint that the effects of the present invention are more excellent, the number of rings is preferably 1 or 2 and more preferably 1. In a case where the first blocked isocyanate compound includes a fused ring, the number of rings constituting the fused ring is counted, for example, the number of rings in the naphthalene ring is counted as 2.

From the viewpoint that the strength of the formed pattern is excellent and the effects of the present invention are more excellent, the number of blocked isocyanate groups in the first blocked isocyanate compound is preferably 2 to 5, more preferably 2 or 3, and still more preferably 2.

From the viewpoint that the effects of the present invention are more excellent, the first blocked isocyanate compound is preferably a blocked isocyanate compound represented by Formula Q.

B¹-A¹-L¹-A²-B² Formula Q

In Formula Q, B¹ and B² each independently represent a blocked isocyanate group.

The blocked isocyanate group is not particularly limited, but from the viewpoint that the effects of the present invention are more excellent, a group in which an isocyanate group is blocked with an oxime compound is preferable, and a group in which an isocyanate group is blocked with methyl ethyl ketoxime (specifically, a group represented by *—NH—C(═O)—O—N═C(CH₃)—C₂H₅; * represents a bonding position with A¹ or A²) is more preferable.

B¹ and B² are preferably the same group.

In Formula Q, A¹ and A² each independently represent a single bond or an alkylene group having 1 to 10 carbon atoms, and an alkylene group having 1 to 10 carbon atoms is preferable.

The alkylene group may be linear, branched, or cyclic, and is preferably linear.

The number of carbon atoms in the alkylene group is 1 to 10, and from the viewpoint that the effects of the present invention are more excellent, is preferably 1 to 5, more preferably 1 to 3, and still more preferably 1.

A¹ and A² are preferably the same group.

In Formula Q, L¹ represents a divalent linking group.

Specific examples of the divalent linking group include a divalent hydrocarbon group.

Specific examples of the divalent hydrocarbon group include a divalent saturated hydrocarbon group, a divalent aromatic hydrocarbon group, and a group formed by linking two or more of these groups.

The divalent saturated hydrocarbon group may be linear, branched, or cyclic, and from the viewpoint that the effects of the present invention are more excellent, is preferably cyclic. From the viewpoint that the effects of the present invention are more excellent, the number of carbon atoms in the divalent saturated hydrocarbon group is preferably 4 to 15, more preferably 5 to 10, and still more preferably 5 to 8.

The divalent aromatic hydrocarbon group preferably has 5 to 20 carbon atoms, and examples thereof include a phenylene group. The divalent aromatic hydrocarbon group may have a substituent (for example, an alkyl group).

Among these, as the divalent linking group, a linear, branched, or cyclic divalent saturated hydrocarbon group having 5 to 10 carbon atoms, a group in which a cyclic saturated hydrocarbon group having 5 to 10 carbon atoms is linked to a linear alkylene group having 1 to 3 carbon atoms, a divalent aromatic hydrocarbon group which may have a substituent, or a group in which a divalent aromatic hydrocarbon group is linked to a linear alkylene group having 1 to 3 carbon atoms is preferable, a cyclic divalent saturated hydrocarbon group having 5 to 10 carbon atoms or a phenylene group which may have a substituent is more preferable, a cyclohexylene group or a phenylene group which may have a substituent is still more preferable, and a cyclohexylene group is particularly preferable.

From the viewpoint that the effects of the present invention are more excellent, the blocked isocyanate compound represented by Formula Q is particularly preferably a blocked isocyanate compound represented by Formula QA.

B^{1a}-A^{1a}-L^{1a}-A^{2a}-B^{2a} Formula QA

In Formula QA, B^{1a} and B^{2a} each independently represent a blocked isocyanate group. Suitable aspects of B^{1a} and B^{2a} are the same as those of B¹ and B² in Formula Q.

In Formula QA, A^{1a} and A^{2a} each independently represent a divalent linking group. A suitable aspect of the divalent linking group in A^{1a} and A^{2a} is the same as those of A¹ and A² in Formula Q.

In Formula QA, L^{1a} represents a cyclic divalent saturated hydrocarbon group or a divalent aromatic hydrocarbon group.

The number of carbon atoms in the cyclic divalent saturated hydrocarbon group in L^{1a} is preferably 5 to 10, more preferably 5 to 8, still more preferably 5 or 6, and particularly preferably 6.

A suitable aspect of the divalent aromatic hydrocarbon group in L^{1a} is the same as that of L¹ in Formula Q.

Among these, L^{1a} is preferably a cyclic divalent saturated hydrocarbon group, more preferably a cyclic divalent saturated hydrocarbon group having 5 to 10 carbon atoms, still more preferably a cyclic divalent saturated hydrocarbon group having 5 to 8 carbon atoms, particularly preferably a cyclic divalent saturated hydrocarbon group having 5 or 6 carbon atoms, and most preferably a cyclohexylene group.

Specific examples of the first blocked isocyanate compound are shown below, but the first blocked isocyanate compound is not limited thereto.

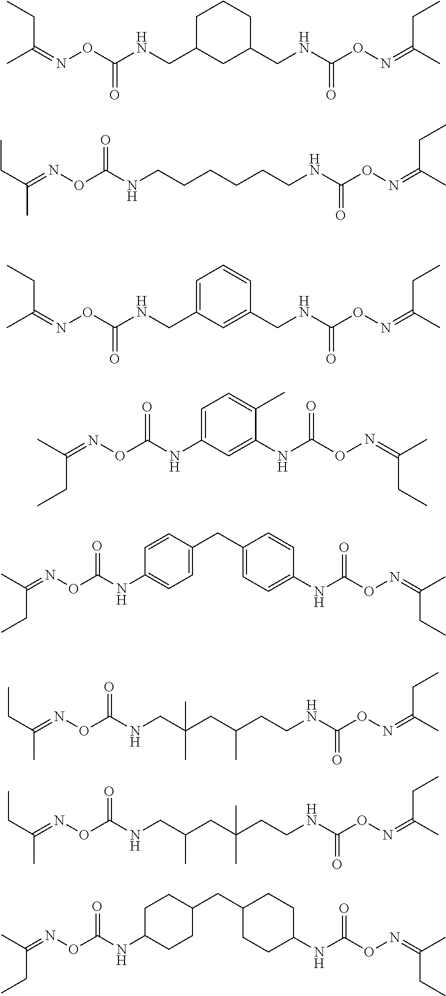

The photosensitive composition layer may include only one kind of first blocked isocyanate compound, or may include two or more kinds of first blocked isocyanate compounds.

From the viewpoint that the effects of the present invention are more excellent, a content of the first blocked isocyanate compound is preferably 0.5% to 25% by mass, more preferably 1% to 20% by mass, and still more preferably 2% to 15% by mass with respect to the total mass of the photosensitive composition layer.

The first blocked isocyanate compound is obtained, for example, by reacting an isocyanate group of a compound having an isocyanate group (for example, a compound in which B¹ and B² in Formula Q described above are isocyanate groups) with the blocking agent.

(Second Blocked Isocyanate Compound)

It is preferable that the blocked isocyanate compound includes a blocked isocyanate compound having an NCO value of less than 4.5 mmol/g (hereinafter, also referred to as a “second blocked isocyanate compound”). As a result, generation of development residue can be suppressed after the photosensitive composition layer is subjected to pattern exposure and development.

The NCO value of the second blocked isocyanate compound is less than 4.5 mmol/g, preferably 2.0 to 4.5 mmol/g and more preferably 2.5 to 4.0 mmol/g.

A dissociation temperature of the second blocked isocyanate compound is preferably 100° C. to 160° C. and more preferably 110° C. to 150° C.

Specific examples of a blocking agent having a dissociation temperature of 1000 to 160° C. are as described above.

From the viewpoint of improvement of brittleness of a film, improvement of adhesive force onto the object to be transferred, or the like, the second blocked isocyanate compound preferably has an isocyanurate structure. The blocked isocyanate compound having an isocyanurate structure can be obtained, for example, by isocyanurate-forming and protecting hexamethylene diisocyanate.

From the viewpoint that it is easier to make the dissociation temperature in a preferred range and to reduce the development residue than a compound not having an oxime structure, as the blocked isocyanate compound having an isocyanurate structure, a compound having an oxime structure, in which an oxime compound is used as the blocking agent, is preferable.

From the viewpoint of strength of a pattern to be formed, the second blocked isocyanate compound may have a polymerizable group. As the polymerizable group, a radically polymerizable group is preferable.

Examples of the polymerizable group include a (meth)acryloxy group, a (meth)acrylamide group, an ethylenically unsaturated group such as styryl group, and an epoxy group such as a glycidyl group. Among these, as the polymerizable group, from the viewpoint of surface shape of the surface of the pattern to be obtained, a development speed, and reactivity, an ethylenically unsaturated group is preferable, and a (meth)acryloxy group is more preferable.

Specific examples of the second blocked isocyanate compound are shown below, but the second blocked isocyanate compound is not limited thereto.

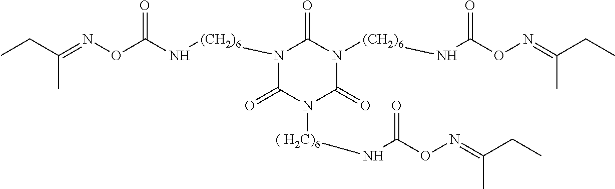

As the second blocked isocyanate compound, a commercially available product can be used. Examples of the commercially available product of the blocked isocyanate compound include KARENZ (product name) AOI-BM, KARENZ (product name) MOI-BM, KARENZ (product name) AOI-BP, KARENZ (product name) MOI-BP, and the like [all manufactured by SHOWA DENKO K.K.], and block-type DURANATE series [for example, DURANATE (product name) TPA-B80E, manufactured by Asahi Kasei Corporation].

The photosensitive composition layer may include only one kind of second blocked isocyanate compound, or may include two or more kinds of second blocked isocyanate compounds.

In a case where the photosensitive composition layer includes the second blocked isocyanate compound, from the viewpoint that the generation of development residue can be further reduced, a content of the second blocked isocyanate compound is preferably 0.5% to 25% by mass, more preferably 1% to 20% by mass, and still more preferably 2% to 15% by mass with respect to the total mass of the photosensitive composition layer.

In a case where the photosensitive composition layer includes the first blocked isocyanate compound and the second blocked isocyanate compound, from the viewpoint of bending resistance and reduction in moisture permeability, a mass ratio (first blocked isocyanate compound/second blocked isocyanate compound) of the content of the first blocked isocyanate compound to the content of the second blocked isocyanate compound is preferably 10/90 to 90/10, more preferably 15/85 to 70/30, and still more preferably 15/85 to 50/50.

[Polymer Including Structural Unit Having Carboxylic Acid Anhydride Structure]

The photosensitive composition layer may further include, as the binder, a polymer (hereinafter also referred to as a “polymer B”) including a structural unit having a carboxylic acid anhydride structure. In a case where the photosensitive composition layer includes the polymer B, the developability and the hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5- to 7-membered ring, more preferably a 5-membered ring or a 6-membered ring, and still more preferably a 5-membered ring.

The structural unit having a carboxylic acid anhydride structure is preferably a structural unit including a divalent group obtained by removing two hydrogen atoms from a compound represented by Formula P-1 in a main chain, or a structural unit in which a monovalent group obtained by removing one hydrogen atom from a compound represented by Formula P-1 is bonded to the main chain directly or through a divalent linking group.

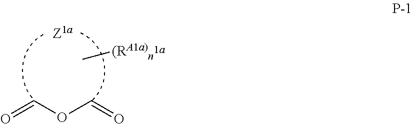

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{la} is preferably an integer of 0 to 4, more preferably an integer of 0 to 2, and still more preferably 0.

In a case where n^{1a} represents an integer of 2 or more, a plurality of R^{A1a}'s may be the same or different from each other. In addition, the plurality of R^{A1a}'s may be bonded to each other to form a ring, but it is preferable that they are not bonded to each other to form a ring.

As the structural unit having a carboxylic acid anhydride structure, a structural unit derived from an unsaturated carboxylic acid anhydride is preferable, a structural unit derived from an unsaturated cyclic carboxylic acid anhydride is more preferable, a structural unit derived from an unsaturated aliphatic carboxylic acid anhydride is still more preferable, a structural unit derived from maleic acid anhydride or itaconic acid anhydride is particularly preferable, and a structural unit derived from maleic acid anhydride is most preferable.

The polymer B may have only one kind of structural unit having a carboxylic acid anhydride structure, or two or more kinds thereof.

A content of the structural unit having a carboxylic acid anhydride structure is preferably 0% to 60% by mole, more preferably 5% to 40% by mole, and still more preferably 10% to 35% by mole with respect to the total amount of the polymer B.

The photosensitive composition layer may include only one kind of polymer B, or may include two or more kinds of polymers B.

From the viewpoint of patterning properties and reliability, a content of the residual monomer of each structural unit of the polymer B in the photosensitive composition layer is preferably 1000 ppm by mass or less, more preferably 500 ppm by mass or less, and still more preferably 100 ppm by mass or less with respect to the total mass of the polymer B. The lower limit is not particularly limited, but is preferably 0.1 ppm by mass or more and more preferably 1 ppm by mass or more.

In a case where the photosensitive composition layer includes the polymer B, from the viewpoint of the developability and the hardness after curing, a content of the polymer B is preferably 0.1% to 30% by mass, more preferably 0.2% to 20% by mass, still more preferably 0.5% to 20% by mass, and particularly preferably 1% to 20% by mass with respect to the total mass of the photosensitive composition layer.

[Heterocyclic Compound]

It is preferable that the photosensitive composition layer includes a heterocyclic compound.

A heterocyclic ring included in the heterocyclic compound may be either a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, a pyridine compound, and a pyrimidine compound.

Among these, as the heterocyclic compound, at least one compound selected from the group consisting of a triazole compound, a benzotriazole compound, a tetrazole compound, a thiadiazole compound, a triazine compound, a rhodanine compound, a thiazole compound, a benzimidazole compounds, a benzoxazole compound, and a pyridine compound is preferable, and at least one compound selected from the group consisting of a triazole compound, a benzotriazole compound, a tetrazole compound, a thiadiazole compound, a thiazole compound, a benzothiazole compound, a benzimidazole compound, a benzoxazole compound, and a pyridine compound is more preferable.

Preferred specific examples of the heterocyclic compound are shown below. The following compounds can be exemplified as a triazole compound and a benzotriazole compound.

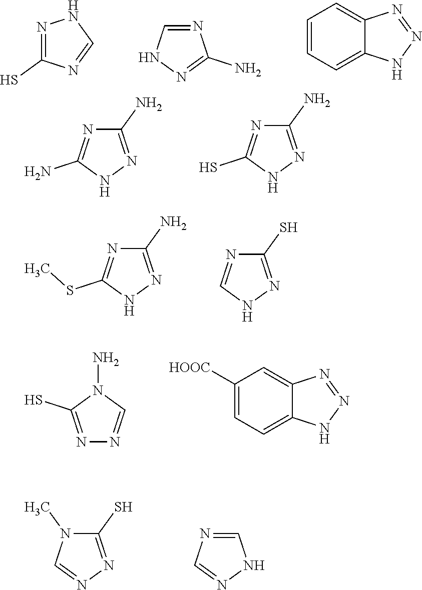

Examples of the tetrazole compound include the following compounds.

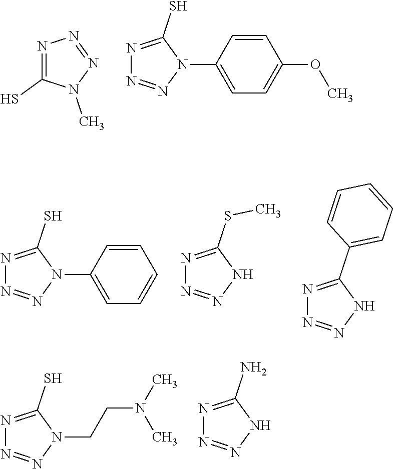

Examples of the thiadiazole compound include the following compounds.

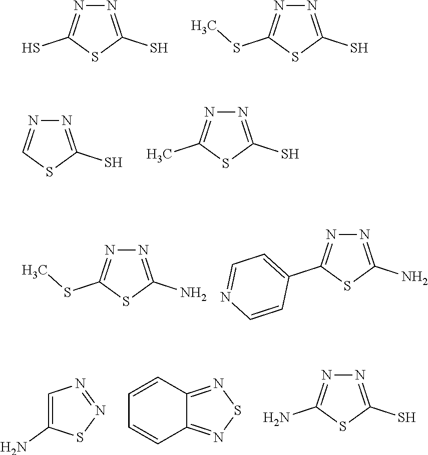

Examples of the triazine compound include the following compounds.

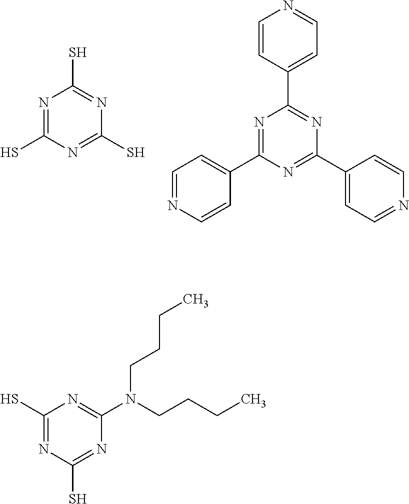

The following compounds can be exemplified as a rhodanine compound.

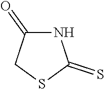

Examples of the thiazole compound include the following compounds.

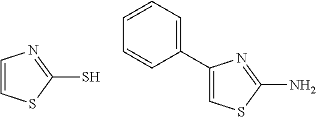

Examples of the benzothiazole compound include the following compounds.

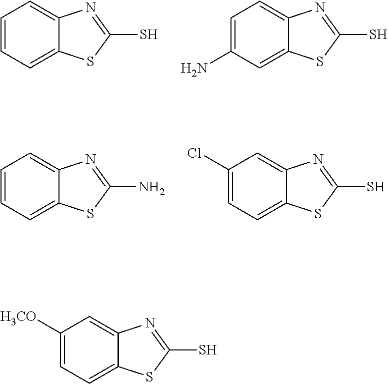 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

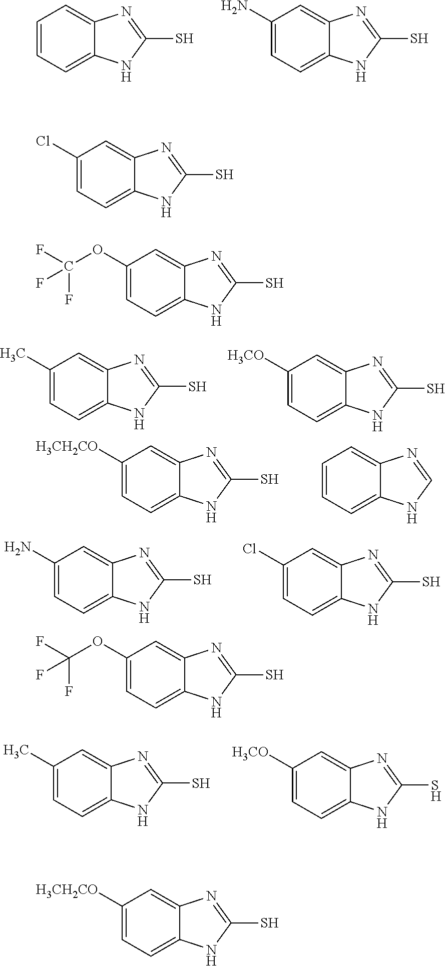

Examples of the benzoxazole compound include the following compounds.

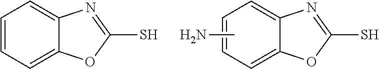

Examples of the pyridine compound include (iso)nicotinic acid and (iso)nicotinamide.

The photosensitive composition layer may include only one kind of heterocyclic compound, or may include two or more kinds of heterocyclic compounds.

In a case where the photosensitive composition layer includes the heterocyclic compound, a content of the heterocyclic compound is preferably 0.01% to 20% by mass, more preferably 0.1% to 10% by mass, still more preferably 0.3% to 8% by mass, and particularly preferably 0.5% to 5% by mass with respect to the total mass of the photosensitive composition layer.

[Aliphatic Thiol Compound]

It is preferable that the photosensitive composition layer includes an aliphatic thiol compound.

In a case where the photosensitive composition layer includes the aliphatic thiol compound, the aliphatic thiol compound undergoes an ene-thiol reaction with a radically polymerizable compound having an ethylenically unsaturated group, so that a film to be formed is suppressed from being cured and shrunk and the stress is relieved.

As the aliphatic thiol compound, a monofunctional aliphatic thiol compound or a polyfunctional aliphatic thiol compound (that is, a bi- or higher functional aliphatic thiol compound) is preferable.

Among these, as the aliphatic thiol compound, for example, from the viewpoint of adhesiveness (in particular, adhesiveness after exposure) of the pattern to be formed, a polyfunctional aliphatic thiol compound is preferable.

In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, a molecular weight of the polyfunctional aliphatic thiol compound is more preferably 100 to 1,500 and still more preferably 150 to 1,000.

From the viewpoint of the adhesiveness of the pattern to be formed, the number of functional groups in the polyfunctional aliphatic thiol compound is, for example, preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,4-bis(3-mercaptobutyryloxy)butane, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among these, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive composition layer may include only one kind of aliphatic thiol compound, or may contain two or more kinds of aliphatic thiol compounds.

In a case where the photosensitive composition layer includes the aliphatic thiol compound, a content of the aliphatic thiol compound is preferably 5% by mass or more, more preferably 5% to 50% by mass, still more preferably 5% to 30% by mass, and particularly preferably 8% to 20% by mass with respect to the total mass of the photosensitive composition layer.

[Surfactant]

It is preferable that the photosensitive composition layer includes a surfactant.

Examples of the surfactant include the surfactants described in paragraph [0017] of JP4502784B and paragraphs [0060] to [0071] of JP2009-237362A.

As the surfactant, a fluorine-based surfactant or a silicone-based surfactant is preferable.

Examples of a commercially available product of the fluorine-based surfactant include: MEGAFACE (product name) F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP. MFS-330, EXP. MFS-578, EXP. MFS-579, EXP. MFS-586, EXP. MFS-587, R-41, R-41-LM, R-01, R-40, R-40-LM, RS-43, TF-1956, RS-90, R-94, RS-72-K, and DS-21 (all manufactured by DIC Corporation); FLUORAD (product name) FC430, FC431, and FC171 (all manufactured by Sumitomo 3M Ltd.); SURFLON (product name)S-382, SC-101, SC-103, SC-104, SC-105, SC-1068, SC-381, SC-383, 5-393, and KH-40 (all manufactured by Asahi Glass Co., Ltd.); PolyFox (product name) PF636, PF656, PF6320, PF6520, and PF7002 (all manufactured by OMNOVA Solutions Inc.); and FTERGENT (product name) 710FM, 610FM, 601AD, 601ADH2, 602A, 215M, and 245F (all manufactured by NEOS Co., Ltd.).

In addition, as the fluorine-based surfactant, an acrylic compound which has a molecular structure having a functional group containing a fluorine atom and in which the functional group containing a fluorine atom is broken to volatilize a fluorine atom by applying heat to the molecular structure can also be suitably used. Examples of such a fluorine-based surfactant include MEGAFACE (product name) DS series manufactured by DIC Corporation (The Chemical Daily (Feb. 22, 2016) and Nikkei Business Daily (Feb. 23, 2016)), for example, MEGAFACE (product name) DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can also be preferably used.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably an ethyleneoxy group and a propyleneoxy group) can be preferably used.

As the fluorine-based surfactant, a fluorine-containing polymer having an ethylenically unsaturated bond-containing group in the side chain can be used. Examples thereof include MEGAFACE (product name) RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (product name) L10, L31, L61, L62, 10R5, 17R2, and 25R2 (all manufactured by BASF SE), TETRONIC (product name) 304, 701, 704, 901, 904, and 150R1 (all manufactured by BASF SE), SOLSPERSE (product name) 20000 (manufactured by Lubrizol Corporation), NCW-101, NCW-1001, and NCW-1002 (all manufactured by FUJIFILM Wako Pure Chemical Corporation), PIONIN (product name) D-6112, D-6112-W, and D-6315 (all manufactured by Takemoto Oil&Fat Co., Ltd.), and OLFINE E1010 and SURFYNOL 104, 400, and 440 (all manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL (product name) 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all manufactured by Shin-Etsu Silicone Co., Ltd.), F-4440, TSF-4300, TSF-4445, TSF-4460, and TSF-4452 (all manufactured by Momentive Performance Materials Co., Ltd.), and BYK307, BYK323, and BYK330 (all manufactured by BYK Chemie).

The photosensitive composition layer may include only one kind of surfactant, or may include two or more kinds of surfactants.

In a case where the photosensitive composition layer includes the surfactant, a content of the surfactant is preferably 0.01% to 3% by mass, more preferably 0.05% to 1% by mass, and still more preferably 0.1% to 0.8% by mass with respect to the total mass of the photosensitive composition layer.

[Hydrogen Donating Compound]

It is preferable that the photosensitive composition layer includes a hydrogen donating compound. The hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537A), JP1989-033104A (JP-S64-033104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-042965B (JP-S48-042965B) (tributyl tin acetate and the like), a hydrogen donor described in JP1980-034414B (JP-S55-034414B), and a sulfur compound described in JP1994-308727A (JP-H6-308727A) (trithiane and the like).

The photosensitive composition layer may include only one kind of hydrogen donating compound, or may include two or more kinds of hydrogen donating compounds.

In a case where the photosensitive composition layer includes the hydrogen donating compound, from the viewpoint of improving a curing rate by balancing the polymerization growth rate and the chain transfer, a content of the hydrogen donating compound is preferably 0.01% to 10% by mass, more preferably 0.03% to 5% by mass, and still more preferably 0.05% to 3% by mass with respect to the total mass of the photosensitive composition layer.

[Other Components]

The photosensitive composition layer may include a component other than the above-described components (hereinafter also referred to as “other components”). Examples of the other components include particles (for example, metal oxide particles) and a colorant. In addition, examples of the other components include a thermal polymerization inhibitor described in paragraph [0018] of JP4502784B and other additives described in paragraphs [0058] to [0071] of JP2000-310706A.

The photosensitive composition layer may include particles for the purpose of adjusting refractive index, light-transmitting property, and the like. Examples of the particles include metal oxide particles.

Examples of a metal in the metal oxide particles also include semi-metals such as B, Si, Ge, As, Sb, and Te.

From a viewpoint of transparency of a pattern, an average primary particle diameter of the particles is, for example, preferably 1 to 200 nm, and more preferably 3 to 80 nm. The average primary particle diameter of the particles is calculated by measuring particle diameters of 200 random particles using an electron microscope, and arithmetically averaging the measurement results. In a case where the shape of the particle is not a spherical shape, the longest side is set as the particle diameter.

The photosensitive composition layer may include only one kind of particles, or may include two or more kinds of particles. In addition, in a case where the photosensitive composition layer includes the particles, it may include only one kind of particles having different metal types, sizes, and the like, or may include two or more kinds thereof.

It is preferable that the photosensitive composition layer does not include particles, or the content of the particles is more than 0% by mass to 35% by mass or less with respect to the total mass of the photosensitive composition layer; it is more preferable that the photosensitive composition layer does not include particles, or the content of the particles is more than 0% by mass to 10% by mass or less with respect to the total mass of the photosensitive composition layer; it is still more preferable that the photosensitive composition layer does not include particles, or the content of the particles is more than 0% by mass to 5% by mass or less with respect to the total mass of the photosensitive composition layer; it is particularly preferable that the photosensitive composition layer does not include particles, or the content of the particles is more than 0% by mass to 1% by mass or less with respect to the total mass of the photosensitive composition layer; and it is the most preferable that the photosensitive composition layer does not include particles.

The photosensitive composition layer may include a trace amount of a colorant (for example, a pigment and a dye), but for example, from the viewpoint of transparency, it is preferable that the photosensitive composition layer does not substantially include the colorant. In a case where the photosensitive composition layer includes the colorant, a content of the colorant is preferably less than 1% by mass, and more preferably less than 0.1% by mass with respect to the total mass of the photosensitive composition layer.

[Impurities and the Like]

The photosensitive composition layer may include a predetermined amount of impurities.

Examples of the impurities include sodium, potassium, magnesium, calcium, iron, manganese, copper, aluminum, titanium, chromium, cobalt, nickel, zinc, tin, halogen, and ions of these. Among these, halide ion (particularly, chloride ion, bromide ion, or iodide ion), sodium ion, and potassium ion are easily mixed as impurities, so that the following content is preferable.

A content of the impurities in the photosensitive composition layer is preferably 80 ppm or less, more preferably 10 ppm or less, and still more preferably 2 ppm or less on a mass basis. The content of the impurities in the photosensitive composition layer may be 1 ppb or more or 0.1 ppm or more on a mass basis.

Specific examples of the content of the impurities in the photosensitive composition layer include an aspect in which all the above-described impurities are 0.6 ppm on a mass basis.

Examples of a method for keeping the impurities in the range include selecting a raw material having a low content of impurities as a raw material for the photosensitive composition layer, preventing the impurities from being mixed in a case of forming the photosensitive composition layer, and washing and removing the impurities. By such a method, the amount of impurities can be kept within the range.

The impurities can be quantified by a known method such as inductively coupled plasma (ICP) emission spectroscopy, atomic absorption spectroscopy, and ion chromatography.

In addition, it is preferable that the content of compounds such as benzene, formaldehyde, trichloroethylene, 1,3-butadiene, carbon tetrachloride, chloroform, N,N-dimethylformamide, N,N-dimethylacetamide, and hexane is low in the photosensitive composition layer. A content of these compounds in the photosensitive composition layer is preferably 100 ppm or less, more preferably 20 ppm or less, and still more preferably 4 ppm or less on a mass basis. The lower limit may be 10 ppb or more or 100 ppb or more on a mass basis. The content of these compounds can be suppressed in the same manner as in the metal as impurities. In addition, the compounds can be quantified by a known measurement method.

From the viewpoint of reliability and a laminating property, the content of water in the photosensitive composition layer is preferably 0.01% to 1.0% by mass, and more preferably 0.05% to 0.5% by mass.

[Residual Monomer]

The photosensitive composition layer may include residual monomers of each constitutional unit of the above-described alkali-soluble resin.

From the viewpoint of patterning properties and reliability, a content of the residual monomers is preferably 5,000 ppm by mass or less, more preferably 2,000 ppm by mass or less, and still more preferably 500 ppm by mass or less with respect to the total mass of the alkali-soluble resin. The lower limit is not particularly limited, but is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the photosensitive composition layer. The lower limit is not particularly limited, but is preferably 0.1 ppm by mass or more and more preferably 1 ppm by mass or more.

It is preferable that an amount of residual monomers of the monomers in a case of synthesizing the alkali-soluble resin by a polymer reaction is also within the range. For example, in a case where glycidyl acrylate is reacted with a carboxylic acid side chain to synthesize the alkali-soluble resin, a content of glycidyl acrylate is preferably within the range.

The amount of the residual monomers can be measured by a known method such as liquid chromatography and gas chromatography.

[Thickness of Photosensitive Composition Layer]

The upper limit value of a thickness of the photosensitive composition layer is preferably 20.0 μm or less, more preferably 15.0 μm or less, and still more preferably 10 μm or less.

The lower limit value of the thickness of the photosensitive composition is preferably 1 μm or more, more preferably 3.0 μm or more, still more preferably 4.0 μm or more, and particularly preferably 5.0 μm or more.

The thickness of the photosensitive composition layer is obtained as an average value at 5 random points measured by cross-section observation with a scanning electron microscope (SEM).

[Refractive Index of Photosensitive Composition Layer]

A refractive index of the photosensitive composition layer is preferably 1.47 to 1.56, and more preferably 1.49 to 1.54.

[Color of Photosensitive Composition Layer]

The photosensitive composition layer is preferably achromatic. The a* value of the photosensitive composition layer is preferably −1.0 to 1.0, and the b* value of the photosensitive composition layer is preferably −1.0 to 1.0.

The hue of the photosensitive composition layer can be measured using a colorimeter (CR-221, manufactured by Minolta Co., Ltd.).

[Transmittance of Photosensitive Composition Layer]

A visible light transmittance of the photosensitive composition layer at a film thickness of approximately 1.0 μm is preferably 80% or more, more preferably 90% or more, and most preferably 95% or more.

As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above.

Examples of a preferred value of the transmittance include 87%, 92%, and 98%.

The same applies to a transmittance of the cured film of the photosensitive composition layer at a film thickness of approximately 1 μm.

[Moisture Permeability of Photosensitive Composition Layer]

From the viewpoint of rust preventive property of electrode or wiring line, and viewpoint of device reliability, a moisture permeability of the pattern obtained by curing the photosensitive composition layer (cured film of the photosensitive composition layer) at a film thickness of 40 μm is preferably 500 g/m²·24 hr or less, more preferably 300 g/m²·24 hr or less, and still more preferably 100 g/m²·24 hr or less.

The moisture permeability is measured with a cured film by curing the photosensitive composition layer by exposing the photosensitive composition layer with i-rays at an exposure amount of 300 mJ/cm² and then performing post-baking at 145° C. for 30 minutes.

The moisture permeability is measured according to a cup method of JIS Z0208. It is preferable that the above-described moisture permeability is as above under any test conditions of temperature 40° C. and humidity 90%, temperature 65° C. and humidity 90%, or temperature 80° C. and humidity 95%. Examples of a specific preferred numerical value include 80 g/m²·24 hr, 150 g/m²·24 hr, and 220 g/m²·24 hr.

[Dissolution Rate of Photosensitive Composition Layer]

From the viewpoint of suppressing residue during development, a dissolution rate of the photosensitive composition layer in a 1.0% by mass sodium carbonate aqueous solution is preferably 0.01 μm/sec or more, more preferably 0.10 μm/sec or more, and still more preferably 0.20 μm/sec or more.

From the viewpoint of edge shape of the pattern, it is preferable to be 5.0 μm/sec or less, more preferable to be 4.0 μm/sec or less, and still more preferable to be 3.0 μm/sec or less.

Examples of a specific preferred numerical value include 1.8 μm/sec, 1.0 μm/sec, and 0.7 μm/sec.

The dissolution rate of the photosensitive composition layer in a 1.0% by mass sodium carbonate aqueous solution per unit time is measured as follows.

A photosensitive composition layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive composition layer is dissolved completely (however, the maximum time is 2 minutes).

The dissolution rate of the photosensitive composition layer is obtained by dividing the film thickness of the photosensitive composition layer by the time required for the photosensitive composition layer to dissolve completely. In a case where the photosensitive layer is not dissolved completely in 2 minutes, the dissolution rate of the photosensitive layer is calculated in the same manner as above, from the amount of change in film thickness up to 2 minutes.

A dissolution rate of the cured film (within a film thickness of 1.0 to 10 μm) of the photosensitive composition layer in a 1.0% by mass sodium carbonate aqueous solution is preferably 3.0 μm/sec or less, more preferably 2.0 μm/sec or less, still more preferably 1.0 μm/sec or less, and most preferably 0.2 μm/sec or less. The cured film of the photosensitive composition layer is a film obtained by exposing the photosensitive composition layer with i-rays at an exposure amount of 300 mJ/cm².

Examples of a specific preferred numerical value include 0.8 μm/sec, 0.2 μm/sec, and 0.001 μm/sec.

For development, a shower nozzle of 1/4 MINJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

[Swelling Ratio of Photosensitive Composition Layer]

From the viewpoint of improving pattern forming properties, a swelling ratio of the photosensitive composition layer after exposure with respect to a 1.0% by mass sodium carbonate aqueous solution is preferably 100% or less, more preferably 50% or less, and still more preferably 30% or less.

The swelling ratio of the photosensitive composition layer after exposure with respect to a 1.0% by mass sodium carbonate aqueous solution is measured as follows.

A photosensitive composition layer (within a film thickness of 1.0 to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the film thickness is measured after 30 seconds. Then, an increased proportion of the film thickness after immersion to the film thickness before immersion is calculated. Examples of a specific preferred numerical value include 4%, 13%, and 25%.

[Foreign Substance in Photosensitive Composition Layer]

From the viewpoint of pattern forming properties, the number of foreign substances having a diameter of 1.0 μm or more in the photosensitive composition layer is preferably 10 pieces/mm² or less, and more preferably 5 pieces/mm² or less.

The number of foreign substances is measured as follows.

Any 5 regions (1 mm×1 mm) on a surface of the photosensitive composition layer are visually observed from a normal direction of the surface of the photosensitive composition layer with an optical microscope, the number of foreign substances having a diameter of 1.0 μm or more in each region is measured, and the values are arithmetically averaged to calculate the number of foreign substances.

Examples of a specific preferred numerical value include 0 pieces/mm², 1 pieces/mm², 4 pieces/mm², and 8 pieces/mm².

[Haze of Dissolved Substance in Photosensitive Composition Layer]

From the viewpoint of suppressing generation of aggregates during development, a haze of a solution obtained by dissolving 1.0 cm³ of the photosensitive composition layer in 1.0 liter of a 1.0% by mass sodium carbonate aqueous solution at 30° C. is preferably 60% or less, more preferably 30% or less, still more preferably 10% or less, and most preferably 1% or less.

The haze is measured as follows.

First, a 1.0% by mass sodium carbonate aqueous solution is prepared, and a liquid temperature is adjusted to 30° C. 1.0 cm³ of the photosensitive composition layer is added to 1.0 L of the sodium carbonate aqueous solution. The solution is stirred at 30° C. for 4 hours, being careful not to mix air bubbles. After stirring, the haze of the solution in which the photosensitive composition layer is dissolved is measured. The haze is measured using a haze meter (trade name “NDH4000”, manufactured by Nippon Denshoku Industries Co., Ltd.), a liquid measuring unit, and a liquid measuring cell having an optical path length of 20 mm. Examples of a specific preferred numerical value include 0.4%, 1.0%, 9%, and 24%.

<Refractive Index-Adjusting Layer>

The transfer film may have a refractive index-adjusting layer. The position of the refractive index-adjusting layer is not particularly limited, but the refractive index-adjusting layer is preferably disposed in contact with the photosensitive composition layer. Among these, it is preferable that the transfer film has the temporary support, the photosensitive composition layer, and the refractive index-adjusting layer in this order.

In a case where the transfer film further has a protective film which will be described later, it is preferable that the transfer film has the temporary support, the photosensitive composition layer, the refractive index-adjusting layer, and the protective film in this order.

As the refractive index-adjusting layer, a known refractive index-adjusting layer can be adopted. Examples of a material included in the refractive index-adjusting layer include a binder and particles.

Examples of the binder include the alkali-soluble resin described in the section of “Photosensitive Composition Layer” above.

Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index-adjusting layer preferably includes a metal oxidation inhibitor. In a case where the refractive index-adjusting layer includes a metal oxidation inhibitor, oxidation of metal in contact with the refractive index-adjusting layer can be suppressed.

As the metal oxidation inhibitor, for example, a compound having an aromatic ring including a nitrogen atom in the molecule is preferable. Examples of the metal oxidation inhibitor include imidazole, benzimidazole, tetrazole, mercaptothiadiazole, and benzotriazole.

A refractive index of the refractive index-adjusting layer is preferably 1.60 or more and more preferably 1.63 or more.

The upper limit of the refractive index of the refractive index-adjusting layer is preferably 2.10 or less and more preferably 1.85 or less.

A thickness of the refractive index-adjusting layer is preferably 500 nm or less, more preferably 110 nm or less, and still more preferably 100 nm or less.

The thickness of the refractive index-adjusting layer is preferably 20 nm or more and more preferably 50 nm or more.

The thickness of the refractive index-adjusting layer is obtained as an average value at 5 random points measured by cross-section observation with a scanning electron microscope (SEM).

<Other Layers>

The transfer film may include a layer other than the temporary support, the photosensitive composition layer, and the refractive index-adjusting layer described above.

Examples of other layers include a protective film and an antistatic layer.

The transfer film may have a protective film for protecting the photosensitive composition layer on a surface opposite to the temporary support.

The protective film is preferably a resin film, and a resin film having heat resistance and solvent resistance can be used.

Examples of the protective film include polyolefin films such as a polypropylene film and a polyethylene film. In addition, a resin film composed of the same material as the above-described temporary support may be used as the protective film.

A thickness of the protective film is preferably 1 to 100 μm, more preferably 5 to 50 μm, still more preferably 5 to 40 μm, and particularly preferably 15 to 30 μm. The thickness of the protective film is preferably 1 μm or more from the viewpoint of excellent mechanical hardness, and is preferably 100 μm or less from viewpoint of relatively low cost.

In addition, in the protective film, the number of fisheyes with a diameter of 80 μm or more in the protective film is preferably 5 pieces/m² or less.

The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less.

As a result, it is possible to suppress defects caused by ruggedness due to the particles included in the protective film being transferred to the photosensitive composition layer or a conductive layer.

From the viewpoint of imparting a take-up property, an arithmetic average roughness Ra of a surface of the protective film on a side opposite to the surface in contact with the composition layer is preferably 0.01 μm or more, more preferably 0.02 μm or more, and still more preferably 0.03 μm or more. On the other hand, the arithmetic average roughness Ra is preferably less than 0.50 μm, more preferably 0.40 μm or less, and still more preferably 0.30 μm or less.

From the viewpoint of suppressing defects during transfer, in the protective film, a surface roughness Ra on the surface in contact with the composition layer is preferably 0.01 μm or more, more preferably 0.02 μm or more, and still more preferably 0.03 μm or more. On the other hand, the surface roughness Ra is preferably less than 0.50 μm, more preferably 0.40 μm or less, and still more preferably 0.30 μm or less.

The transfer film may include an antistatic layer.

In a case where the transfer film includes an antistatic layer, since it is possible to suppress generation of static electricity in a case of peeling off the film or the like disposed on the antistatic layer, and also to suppress generation of static electricity due to rubbing against equipment, other films, or the like, for example, it is possible to suppress occurrence of defect in an electronic apparatus.

The antistatic layer is preferably disposed between the temporary support and the photosensitive composition layer.

The antistatic layer is a layer having antistatic properties, and includes at least an antistatic agent. The antistatic agent is not particularly limited, and a known antistatic agent can be adopted.

[Method for Producing Transfer Film]

The method for producing a transfer film according to an embodiment of the present invention is not particularly limited, and known methods can be used.

Above all, a method of applying a photosensitive composition onto a temporary support and performing a drying treatment as necessary to form a photosensitive composition layer (hereinafter, this method is referred to as a “coating method”) is preferable from the viewpoint that the productivity is excellent.

The photosensitive composition used in the coating method preferably includes the above-described components (for example, the polymerizable compound, the alkali-soluble resin, the polymerization initiator, the specific polymerization initiator, and the like) constituting the photosensitive composition layer, and a solvent.

As the solvent, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. As the solvent, a mixed solvent of methyl ethyl ketone and propylene glycol monomethyl ether acetate or a mixed solvent of diethylene glycol ethyl methyl ether and propylene glycol monomethyl ether acetate is preferable.

In addition, as the solvent, an organic solvent (high-boiling-point solvent) having a boiling point of 180° C. to 250° C. can also be used as necessary.

The photosensitive composition may include only one kind of solvent, or may include two or more kinds of solvents.

In a case where the photosensitive composition includes the solvent, the total solid content of the photosensitive composition is preferably 5% to 80% by mass, more preferably 5% to 40% by mass, and still more preferably 5% to 30% by mass to the total mass of the photosensitive composition.

In a case where the photosensitive composition includes the solvent, for example, from the viewpoint of coatability, a viscosity of the photosensitive composition at 25° C. is preferably 1 to 50 mPa·s, more preferably 2 to 40 mPa·s, and still more preferably 3 to 30 mPa·s. The viscosity is measured using a viscometer. As the viscometer, for example, a viscometer (product name: VISCOMETER TV-22) manufactured by Toki Sangyo Co., Ltd. can be suitably used. However, the viscometer is not limited to the above-described viscometer.

In a case where the photosensitive composition includes the solvent, from the viewpoint of coatability, a surface tension of the photosensitive composition at 25° C. is preferably 5 to 100 mN/m, more preferably 10 to 80 mN/m, and still more preferably 15 to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of the method for applying the photosensitive composition include a printing method, a spray coating method, a roll coating method, a bar coating method, a curtain coating method, a spin coating method, and a die coating method (that is, a slit coating method).

Examples of a drying method include natural drying, heating drying, and drying under reduced pressure. The above-described methods can be adopted alone or in combination of two or more thereof.

In the present disclosure, the “drying” means removing at least a part of the solvent included in the composition.

In addition, in a case where the transfer film has a protective film, the transfer film can be produced by affixing the protective film to the photosensitive composition layer.

A method for affixing the protective film to the photosensitive composition layer is not particularly limited, and examples thereof include known methods.

Examples of a device for affixing the protective film to the photosensitive composition layer include known laminators such as a vacuum laminator and an auto-cut laminator.

It is preferable that the laminator is equipped with any heatable roller such as a rubber roller and can perform pressing and heating.

[Method for Producing Laminate]

The photosensitive composition layer can be transferred to an object to be transferred by using the above-described transfer film.

Among these, a method for producing a laminate, including an affixing step of bringing the photosensitive composition layer on the temporary support of the transfer film into contact with a substrate having a conductive layer to affix the photosensitive composition layer to the substrate and obtain a photosensitive composition layer-attached substrate having the substrate, the conductive layer, the photosensitive composition layer, and the temporary support in this order; an exposing step of exposing the photosensitive composition layer in a patterned manner; a developing step of developing the exposed photosensitive composition layer to form a pattern, in which the producing method further includes, between the affixing step and the exposing step or between the exposing step and the developing step, a peeling step of peeling the temporary support from the substrate with a photosensitive composition layer, is preferable.

Hereinafter, the procedure of the steps will be specifically described.

<Affixing Step>

The affixing step is a step of bringing the photosensitive composition layer on the temporary support of the transfer film into contact with a substrate having a conductive layer to affix the photosensitive composition layer to the substrate and obtain a photosensitive composition layer-attached substrate having the substrate, the conductive layer, the photosensitive composition layer, and the temporary support in this order.

An exposed photosensitive composition layer on the temporary support of the transfer film is brought into contact with the substrate having a conductive layer and affixed to the substrate. By this affixing, the photosensitive composition layer and the temporary support are arranged on the substrate having a conductive layer.

In the above-described affixing, the conductive layer and the surface of the photosensitive composition layer are pressure-bonded so that both are in contact with each other. In the above-described aspect, a pattern obtained after exposure and development can be suitably used as an etching resist in a case of etching the conductive layer.

The pressure-bonding method is not particularly limited, and known transfer methods and laminating methods can be used. Among these, it is preferable to superimpose a surface of the photosensitive composition layer on a substrate having a conductive layer, followed by pressurizing and heating with a roll or the like.

A known laminator such as a vacuum laminator and an auto-cut laminator can be used for the affixing.

The substrate having a conductive layer has a conductive layer on the substrate, and any layer may be formed as necessary. That is, the substrate having the conductive layer is a conductive substrate having at least a substrate and a conductive layer arranged on the substrate.

Examples of the substrate include a resin substrate, a glass substrate, and a semiconductor substrate.

Preferred aspects of the substrate are described, for example, in paragraph 0140 of WO2018/155193A, the contents of which are incorporated herein by reference.

As the conductive layer, from the viewpoint of conductivity and a thin wire forming property, at least one layer selected from the group consisting of a metal layer, a conductive metal oxide layer, a graphene layer, a carbon nanotube layer, and a conductive polymer layer is preferable.

In addition, only one conductive layer may be disposed, or two or more conductive layers may be arranged on the substrate. In a case where two or more conductive layers are arranged, it is preferable to have conductive layers made of different materials.

Preferred aspects of the conductive layers are described, for example, in paragraph 0141 of WO2018/155193A, the contents of which are incorporated herein by reference.

As the substrate having a conductive layer, a substrate having at least one of a transparent electrode or a lead wire is preferable. Such a substrate can be suitably used as a substrate for a touch panel.

The transparent electrode can function suitably as a touch panel electrode. The transparent electrode is preferably composed of a metal oxide film such as indium tin oxide (ITO) and indium zinc oxide (IZO), a metal mesh, and a fine metal wire such as a silver nanowire.

Examples of the fine metal wire include thin wire of silver and copper. Among these, silver conductive materials such as silver mesh and silver nanowire are preferable.

As a material of the lead wire, metal is preferable.

Examples of a metal which is the material of the lead wire include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

<Exposing Step>

The exposing step is a step of exposing the photosensitive composition layer in a patterned manner.

Here, the “pattern exposure” refers to exposure in a form of performing the exposure in a patterned manner, that is, a form in which an exposed portion and a non-exposed portion are present.

Detailed arrangement and specific size of the pattern in the pattern exposure are not particularly limited. A pattern formed by the developing step which will be described later preferably includes thin wires having a width of 20 μm or less, and more preferably includes thin wires having a width of 10 μm or less.

As a light source of the pattern exposure, a light source can be appropriately selected, as long as it can emit light at a wavelength region (for example, 365 nm or 405 nm) at which at least the photosensitive composition layer can be cured. Among these, a main wavelength of the exposure light for the exposure in a patterned manner is preferably 365 nm. The main wavelength is a wavelength having the highest intensity.

Examples of the light source include various lasers, a light emitting diode (LED), an ultra-high pressure mercury lamp, a high pressure mercury lamp, and a metal halide lamp.

An exposure amount is preferably 5 to 200 mJ/cm² and more preferably 10 to 200 mJ/cm².

Preferred aspects of the light source, the exposure amount, and the exposing method used for the exposure are described in, for example, paragraphs [0146] and [0147] of WO2018/155193A, the contents of which are incorporated herein by reference.

<Peeling Step>

The peeling step is a step of peeling the temporary support from the photosensitive composition layer-attached substrate between the affixing step and the exposing step, or between the exposing step and the developing step which will be described later.

The peeling method is not particularly limited, and the same mechanism as the cover film peeling mechanism described in paragraphs [0161] and [0162] of JP2010-072589A can be used.

<Developing Step>

The developing step is a step of developing the exposed photosensitive composition layer to form a pattern.

Development of the photosensitive composition layer can be performed using a developer.

As the developer, an alkaline aqueous solution is preferable. Examples of an alkaline compound which can be included in the alkaline aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutylammonium hydroxide, and choline (2-hydroxyethyltrimethyl ammonium hydroxide).

Examples of the developing method include methods such as puddle development, shower development, spin development, and dip development.

Examples of the developer that is suitably used in the present disclosure include the developer described in paragraph [0194] of WO2015/093271A, and examples of the developing method that is suitably used include the developing method described in paragraph [0195] of WO2015/093271A.

The detailed arrangement and the specific size of the pattern to be formed are not particularly limited, but a pattern from which conductive thin wires described later are obtained is preferably formed. A pattern interval is preferably 8 μm or less and more preferably 6 μm or less. The lower limit is not particularly limited, but is 2 μm or more in many cases.

A pattern formed by the procedure (a cured film of the photosensitive composition layer) is preferably achromatic. Specifically, in an L*a*b* color system, the a* value of the pattern is preferably −1.0 to 1.0, and the b* value of the pattern is preferably −1.0 to 1.0.

<Post-Exposing Step and Post-Baking Step>

The above-described method for producing a laminate may have a step of exposing the pattern obtained by the above-described developing step (post-exposing step) and/or a step of heating (post-baking step) the pattern.

In a case where both of the post-exposing step and the post-baking step are included, it is preferable that the post-baking is carried out after the post-exposure.

<Other Steps>

The method for producing a laminate according to the embodiment of the present invention may include any steps (other steps) other than those described above. Examples of the other steps include an etching step and a removal step.

Examples thereof include a step of reducing a visible light reflectivity, which is described in paragraph [0172] of WO2019/022089A, and a step of forming a new conductive layer on an insulating film, which is described in paragraph [0172] of WO2019/022089A, but the other steps are not limited to these steps.

<Etching Step>

The above-described method for producing a laminate may have an etching step of etching the conductive layer in a region where the pattern is not disposed in a laminate to be obtained.

In the above-described etching step, the pattern formed from the above-described photosensitive composition layer by the above-described developing step is used as an etching resist to etch the above-described conductive layer.

As a method for the etching treatment, known methods such as methods by dry etching such as the methods described in paragraphs [0209] and [0210] of JP2017-120435A, paragraphs [0048] to [0054] of JP2010-152155A, and the like, and known plasma etching can be applied.

<Removal Step>

The method for producing a laminate may include a removal step of removing the pattern.

The removal step can be performed as needed, but is preferably performed after the etching step.

The method for removing the pattern is not particularly limited, and examples thereof include a method for removing the pattern by chemical treatment, and it is preferable to use a removing liquid.

Examples of the method for removing the pattern include a method of immersing a laminate having a pattern in a removing liquid under stirring at preferably 30° C. to 80° C., and more preferably 50° C. to 80° C. for 1 to 30 minutes.

Examples of the removing liquid include a removing liquid in inorganic alkali components such as sodium hydroxide and potassium hydroxide, or organic alkali components such as a primary amine compound, a secondary amine compound, a tertiary amine compound, and a quaternary ammonium salt compound are dissolved in water, dimethylsulfoxide, N-methylpyrrolidone, or a mixed solution thereof.

In addition, the removal may be performed by a spray method, a shower method, a paddle method or the like using the removing liquid.

The laminate produced by the method for producing a laminate according to the embodiment of the present invention can be applied to various devices. Examples of the device provided with the above-described laminate include input devices, and a touch panel is preferable and a capacitance type touch panel is more preferable. In addition, the above-described input device can be applied to a display device such as an organic electroluminescent display device and a liquid crystal display device.

In a case where the laminate is applied to a touch panel, it is preferable that the pattern formed from the photosensitive composition layer is used as a protective film for a touch panel electrode. That is, it is preferable that the photosensitive composition layer included in the transfer film is used for formation of a touch panel electrode protective film. The touch panel electrode includes not only a sensor electrode of the touch sensor but also a lead wire.

### EXAMPLES

Hereinafter, the present invention will be described in detail with reference to Examples. The material, the amount used, the ratio, the process contents, the process procedure, and the like shown in the following examples can be appropriately changed, within a range not departing from a gist of the present disclosure. Accordingly, the scope of the present invention is not limited to the following specific examples. “part” and “%” are based on mass unless otherwise specified.

In the following examples, a weight-average molecular weight of a resin is a weight-average molecular weight obtained by performing polystyrene conversion of a value measured by gel permeation chromatography (GPC). Further, a theoretical acid value was used as the acid value.

<Synthesis of Alkali-Soluble Resin A-1>

113.5 g of propylene glycol monomethyl ether was charged into a flask and heated to 90° C. under a nitrogen stream. To this liquid, a solution in which 172 g of styrene, 4.7 g of methyl methacrylate, and 112.1 g of methacrylic acid had been dissolved in 30 g of propylene glycol monomethyl ether and a solution in which 27.6 g of a polymerization initiator V-601 (manufactured by FUJIFILM Wako Pure Chemical Corporation) had been dissolved in 57.7 g of propylene glycol monomethyl ether was simultaneously added dropwise over 3 hours. After the dropwise addition, 2.5 g of V-601 was added three times every hour. Thereafter, the reaction was continued for another 3 hours. Thereafter, the reaction liquid was diluted with 160.7 g of propylene glycol monomethyl ether acetate and 233.3 g of propylene glycol monomethyl ether. The reaction liquid was heated to 100° C. under an air stream, and 1.8 g of tetraethylammonium bromide and 0.86 g of p-methoxyphenol were added thereto. 71.9 g of glycidyl methacrylate (Blemmer GH manufactured by NOF Corporation.) was added dropwise thereto over 20 minutes. The mixture was reacted at 100° C. for 7 hours to obtain a solution of an alkali-soluble resin A-1 (see structural formula described below). The concentration of solid contents of the obtained solution was 36.2% by mass. The weight-average molecular weight in terms of standard polystyrene in GPC was 17000, the dispersity was 2.3, and the acid value of the alkali-soluble resin was 124 mgKOH/g. The amount of residual monomer measured by gas chromatography was less than 0.1% by mass with respect to the solid content of the alkali-soluble resin in any of the monomers.

<Synthesis of Alkali-Soluble Resin A-2>

144.5 g of propylene glycol monomethyl ether was charged into a flask and heated to 90° C. under a nitrogen stream. To this liquid, a solution in which 118.1 g of styrene, 118.1 g of methyl methacrylate, and 59.1 g of methacrylic acid had been dissolved in 40 g of propylene glycol monomethyl ether and a solution in which 27.6 g of a polymerization initiator V-601 (manufactured by FUJIFILM Wako Pure Chemical Corporation) had been dissolved in 71.6 g of propylene glycol monomethyl ether was simultaneously added dropwise over 3 hours. After the dropwise addition, 2.5 g of V-601 was added three times every hour. Thereafter, the reaction was continued for another 3 hours. Thereafter, the reaction liquid was diluted with 129.3 g of propylene glycol monomethyl ether acetate and 93.6 g of propylene glycol monomethyl ether. In this way, a solution of an alkali-soluble resin A-2 (see structural formula described below) was obtained. The concentration of solid contents of the obtained solution was 36.2% by mass. The weight-average molecular weight in terms of standard polystyrene in GPC was 9000, the dispersity was 2.3, and the acid value of the alkali-soluble resin was 130 mgKOH/g. The amount of residual monomer measured by gas chromatography was less than 0.1% by mass with respect to the solid content of the alkali-soluble resin in any of the monomers.

<Synthesis of Alkali-Soluble Resins A-3 to A-6>

Alkali-soluble resins A-3 to A-6 were synthesized in the same manner as the synthesis of the alkali-soluble resin A-1, except that the types of monomers for obtaining each structural unit included in the alkali-soluble resin and the content of each structural unit were changed as appropriate. The amount of residual monomer measured by gas chromatography was less than 0.1% by mass with respect to the solid content of the alkali-soluble resin in any of the monomers.

<Synthesis of Alkali-Soluble Resin A-7>

An alkali-soluble resin A-7 was synthesized in the same manner as the synthesis of the alkali-soluble resin A-2, except that the types of monomers for obtaining each structural unit included in the alkali-soluble resin and the content of each structural unit were changed as appropriate. The amount of residual monomer measured by gas chromatography was less than 0.1% by mass with respect to the solid content of the alkali-soluble resin in any of the monomers.

Structural formulae of the alkali-soluble resins A-1 to A-7 are shown below.

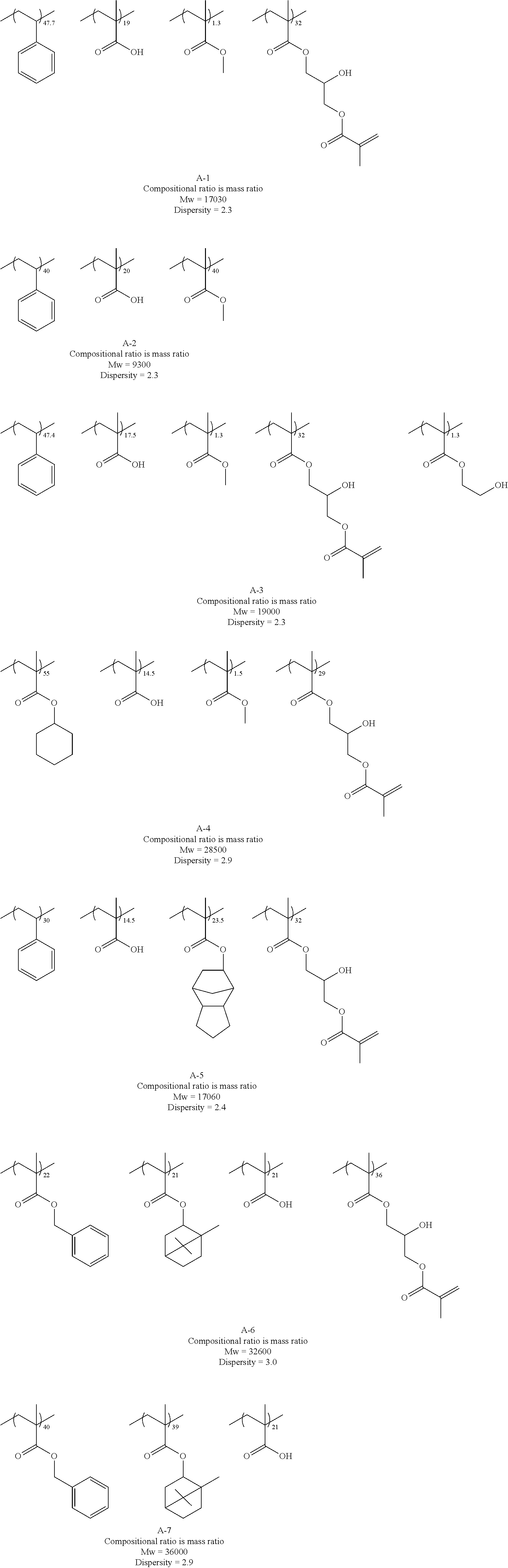

<Synthesis of First Blocked Isocyanate Compound>

Under a nitrogen stream, 453 g of butanone oxime (manufactured by Jdemitsu Kosan Co., Ltd.) was dissolved in 700 μg of methyl ethyl ketone. 500 μg of 1,3-bis(isocyanatomethyl)cyclohexane (cis, trans isomer mixture, manufactured by Mitsui Chemicals Inc., TAKENATE 600) was added dropwise thereto over 1 hour under ice-cooling, and the reaction was performed for another 1 hour after the dropwise addition. Thereafter, the temperature was raised to 40° C. and the reaction was performed for 1 hour. It was confirmed by ¹H-nuclear magnetic resonance (NMR) and high performance liquid chromatography (HPLC) that the reaction was completed to obtain a methyl ethyl ketone solution of a blocked isocyanate compound Q-1 (see the following formula; NCO value: 5.4 mmol/g).

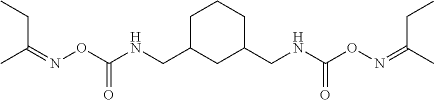 [SMILES: CC/C(C)=N\OC(=O)NCC1CCCC(CNC(=O)O/N=C(/C)CC)C1]

<Second Blocked Isocyanate Compound>

As a second blocked isocyanate compound, Duranate TPA-B80E (manufactured by Asahi Kasei Chemicals Corporation; NCO value: 3.9 mmol/g) was used.

<Preparation of Photosensitive Composition>

Photosensitive compositions A-1 to A-41 and B-1 to B-4 were prepared so that the composition of the solid content was as shown in Table 1 below. In Table 1, the numerical value of each component indicates the content (solid content mass) of each component.

All the photosensitive compositions were coating liquids prepared by mixing and dissolving a mixed solvent of propylene glycol monomethyl ether acetate/propylene glycol monomethyl ether/methyl ethyl ketone=18/60/22 (mass ratio) and each component shown in Table 1 such that the concentration of solid contents of the photosensitive composition (coating liquid) was 25% by mass.

The outline of the components shown by abbreviations in Table 1 is as follows.

(Polymerizable Compound)
A-DCP: trade name, manufactured by Shin-Nakamura Chemical Co., Ltd., tricyclodecane dimethanol diacrylate
A-NOD-N: trade name, manufactured by Shin-Nakamura Chemical Co., Ltd., 1,9-nonanediol diacrylate
DPHA: trade name, manufactured by Shin-Nakamura Chemical Co., Ltd., dipentaerythritol hexaacrylate
TO-2349: ARONIX TO-2349, manufactured by Toagosei Co., Ltd., penta- or hexafunctional monomer obtained by modifying dipentaerythritol polyacrylate with succinic acid (which has a carboxy group)

(Specific Polymerization Initiator)

Structures of the specific polymerization initiators I-1 to I-11 and II-1 to II-3 are as follows.

Here, the specific polymerization initiators I-1 to I-6 and II-1 and II-2 were synthesized with reference to the method described in EP88050B. The specific polymerization initiators I-7 to I-10 were synthesized with reference to the method described in WO2016-017537A. The specific polymerization initiator I-11 was synthesized with reference to the method described in Journal of American Chemical Society, 1961, vol. 83, p. 1237 to 1240. The specific polymerization initiator II-3 was synthesized with reference to the method described in JP2016-079157A.

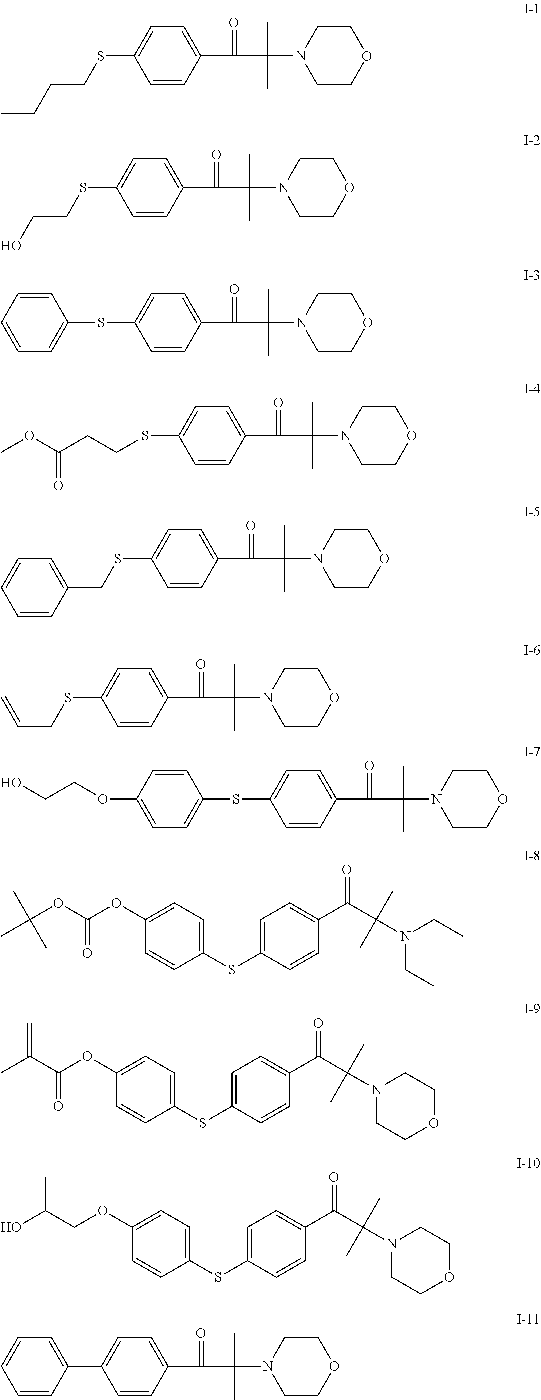

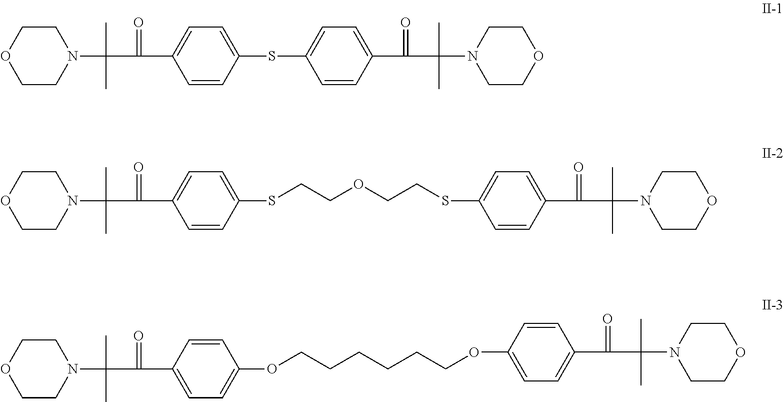 [SMILES: CC(C)(C(=O)c1ccc(Sc2ccc(C(=O)C(C)(C)N3CCOCC3)cc2)cc1)N1CCOCC1 ; CC(C)(C(=O)c1ccc(SCCOCCSc2ccc(C(=O)C(C)(C)N3CCOCC3)cc2)cc1)N1CCOCC1 ; CC(C)(C(=O)c1ccc(OCCCCCCOc2ccc(C(=O)C(C)(C)N3CCOCC3)cc2)cc1)N1CCOCC1]

(Other Polymerization Initiators)
OXE-02: IRGACURE OXE-02, manufactured by BASF SE, 1-[9-ethyl-6-(2-methylbenzoyl)-9H-carbazole-3-yl]ethanone- 1-(O-acetyloxime)
OXE-03: IRGACURE OXE-03, manufactured by BASF SE, 8-[5-(2,4,6-trimethylphenyl)-11-(2-ethylhexyl)-11H-benzo [a]carbazoyl][2-(2,2,3,3-tetrafluoro propoxy)phenyl]methanone-(O-acetyloxime)
Omnirad-907: trade name, manufactured by IGM Resins B. V., see the following formula

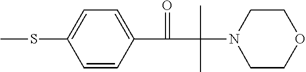 [SMILES: CSc1ccc(C(=O)C(C)(C)N2CCOCC2)cc1]

### Production and Evaluation Test of Transfer Films of Examples 1 to 41 and Comparative Examples 1 to 4

Transfer films of Examples 1 to 41 and Comparative Examples 1 to 4 were produced for each of the following evaluation tests using the above-described photosensitive compositions A-1 to A-41 and B-1 to B-4, and various evaluation tests were performed.

(Bending Resistance)

To a polyethylene terephthalate film (manufactured by Toray Industries, Inc., 16KS40) having a thickness of 16 μm (temporary support), the above-described photosensitive composition was applied using a slit-shaped nozzle such that a thickness after drying was adjusted to 5 μm, and dried at 100° C. for 2 minutes to form a photosensitive composition layer.

Next, a coating liquid for a refractive index-adjusting layer having the following composition was applied to the photosensitive composition layer such that a thickness after drying was adjusted to 70 nm, dried for 1 minute at 80° C., and further dried for 1 minute at 110° C. to form a refractive index-adjusting layer disposed in direct contact with the photosensitive composition layer. A refractive index of the refractive index-adjusting layer was 1.69.

—Composition of Coating Liquid for Forming Refractive Index-Adjusting Layer—
(Meth)acrylic resin (resin having an acid group, copolymer resin of methacrylic acid/allyl methacrylate, weight-average molecular weight: 25,000, compositional ratio (molar ratio)=40/60, solid content: 99.8%): 0.29 parts
ARONIX TO-2349 (monomer having a carboxylic acid group, manufactured by Toagosei Co., Ltd.): 0.04 parts
NanoUse OZ-S30M (ZrO₂ particles, solid content: 30.5%, methanol 69.5%, refractive index: 2.2, average particle diameter: approximately 12 nm, manufactured by Nissan Chemical Corporation): 4.80 parts
BT120 (benzotriazole, manufactured by Johoku Chemical Industry Co., Ltd.): 0.03 parts
MEGAFACE F444 (fluorine-based surfactant, manufactured by DIC Corporation): 0.01 parts
Ammonia aqueous solution (2.5%): 7.80 parts
Distilled water: 24.80 parts
Methanol: 76.10 parts

For a laminate obtained as described above, in which the photosensitive composition layer and the refractive index-adjusting layer which was disposed to be directly adjacent to the photosensitive composition layer were provided on the temporary support in this order, a polyethylene terephthalate film (protective film) having a thickness of 16 μm was pressure-bonded onto the refractive index-adjusting layer to produce a transfer film.

After peeling off the protective film from the obtained transfer film, the transfer films were laminated on both surfaces of a polyethylene terephthalate film of COSMOSHINE A4300 (thickness: 50 μm) manufactured by TOYOBO Co., Ltd.), which had been heat-treated at 145° C. for 30 minutes, to form a laminate A having a laminated structure of temporary support/photosensitive composition layer/refractive index-adjusting layer/COSMOSHINE A4300 (thickness: 50 μm)/refractive index-adjusting layer/photosensitive composition layer/temporary support. In the laminating conditions, a laminating roll temperature was set as 110° C., a linear pressure was set as 3 N/cm, and a transportation speed was set as 2 m/min.

Thereafter, both surfaces were exposed through the temporary support using a proximity type exposure machine (manufactured by Hitachi High-Tech Electronics Engineering Co., Ltd.) including an ultra-high pressure mercury lamp with an exposure amount of 100 mJ/cm² (i-rays). After peeling off the temporary supports on both sides, exposure was further performed with an exposure amount of 400 mJ/cm² (i-rays), and post baking was performed at 145° C. for 30 minutes to cure the photosensitive composition layer, thereby forming a cured film.

In this way, a bending resistance evaluation sample consisting of cured film having a thickness of 10 μm/refractive index-adjusting layer/COSMOSHINE A4300 (thickness: 50 μm)/refractive index-adjusting layer/cured film having a thickness of 10 μm.

Bending resistance was evaluated as follows using the bending resistance evaluation sample.

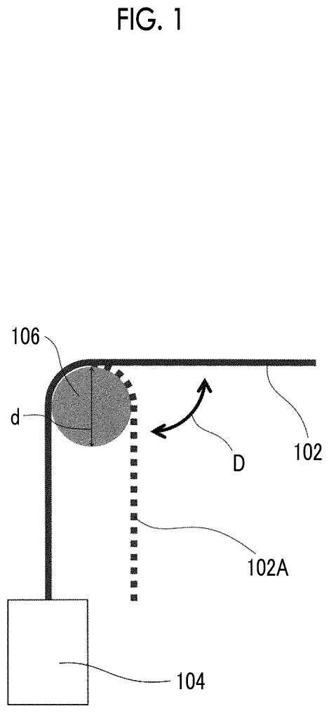

FIG. 1 is a schematic cross-sectional view showing a state of a bending resistance evaluation sample in a bending resistance evaluation.

The bending resistance evaluation sample obtained above was cut into a rectangle of 5 cm×12 cm. As shown in FIG. 1, in the cut bending resistance evaluation sample 102, a weight 104 of 100 g was attached to one of the short sides and weighted, and was held so as to be in contact with a metal rod 106 having a diameter of d mm at an angle of 900 (state of the bending resistance evaluation sample 102 in FIG. 1). Thereafter, the bending resistance evaluation sample 102 was bent 1800 so as to be wound around the metal rod 106 (state of the bending resistance evaluation sample 102A after bending in FIG. 1), the movement (reciprocating direction D) of returning to the original position was reciprocated 10 times, and then the presence or absence of cracks on the surface of the sample was visually confirmed.

The above-described operation was performed while changing the diameter d of the metal rod 106, and the smallest d at which cracks did not occur was obtained. In the following evaluation standard, A was most excellent in bending resistance. A or B is preferable, and A is more preferable.

A: smallest d which did not cause cracks was 2 mm or less.

B: smallest d which did not cause cracks was more than 2 mm and 3 mm or less.

C: smallest d which did not cause cracks was more than 3 mm.

(Moisture Permeability)

To a polyethylene terephthalate (PET) film having a thickness of 75 μm (temporary support), the photosensitive composition was applied using a slit-shaped nozzle, and dried to form a photosensitive composition layer having a thickness of 8 μm, thereby obtaining a transfer film for sample production.

Next, the transfer film for same production was laminated on PTFE (tetrafluoroethylene resin) membrane filter FP-100-100 manufactured by Sumitomo Electric Industries, Ltd., to form a laminate B-1 having a layer structure of “temporary support/photosensitive composition layer having a thickness of 8 μm/membrane filter”. Laminating conditions were that a temperature of the membrane filter was 40° C., a temperature of a laminating roll was 110° C., a linear pressure was 3 N/cm, and a transportation speed was 2 m/min.

Next, the temporary support was peeled off from the laminate B-1.

A procedure in which the transfer film for sample production was further laminated on the exposed photosensitive composition layer of the laminate Ain the same manner as described above, and the temporary support was peeled off from the obtained laminate was repeated 4 times to form a laminate B-2 having a laminated structure of “photosensitive composition layer having a total thickness of 40 μm/membrane filter”.

The photosensitive composition layer of the obtained laminate B-2 was entirely exposed using a high-pressure mercury lamp. The integrated exposure amount measured with a 365 nm illuminance meter was 375 mJ/cm². The exposed laminate was post-baked at 140° C. for 30 minutes in an oven to cure the photosensitive composition layer, thereby forming a cured film.

In this way, a moisture permeability measuring sample having a laminated structure of “cured film having a thickness of 40 μm/membrane filter” was obtained.

The measurement of the moisture permeability was performed by a cup method using the sample for measuring moisture permeability, with reference to JIS-Z-0208 (1976). Hereinafter, the details will be described.

First, a circular sample having a diameter of 70 mm was cut from the sample for measuring moisture permeability. Next, 20 g of dried calcium chloride was put in a measurement cup, and covered with the circular sample, and accordingly, a lid-attached measurement cup was prepared.

This lid-attached measurement cup was left in a constant-temperature and constant-humidity tank for 24 hours under the condition of 65° C. with 90% RH. A water vapor transmission rate (WVTR) of the circular sample (unit: g/(m²-day)) was calculated from a change in mass of the lid-attached measurement cup before and after the leaving.

The measurement described above was performed three times and an average value of the WVTRs in three times of the measurement was calculated.

A moisture permeability was evaluated based on the reduction rate (%) of the WVTR of each of Examples in a case where the WVTR of Comparative Example 1 was set to 100%. As the value of the reduction rate is larger, the moisture permeability was further lowered as compared with Comparative Example 1, which is preferable as a protective film. In the following evaluation standard, A or B is preferable, and A is more preferable.

In the measurement, the WVTR of the circular sample having a laminated structure of “cured film having a thickness of 40 μm/membrane filter” was measured as described above. However, the WVTR of the membrane filter was extremely higher than the WVTR of the exposed photosensitive composition layer, and accordingly, in the above-described measurement, the WVTR of the cured film itself was substantially measured.

A: reduction rate of the WVTR was 40% or more.

B: reduction rate of the WVTR was 20% or more and less than 40%.

C: reduction rate of the WVTR was less than 20%.

(ITO Adhesiveness)

A transfer film was produced by performing the same operation as the above-described evaluation of bending resistance.

By peeling off the cover film from the obtained transfer film and laminating the transfer film on glass laminated with indium tin oxide (ITO), the photosensitive composition layer of the transfer film was transferred to a surface of the ITO substrate to obtain a laminate C having a laminated structure of “temporary support/photosensitive composition layer/refractive index-adjusting layer/ITO layer/substrate (glass)”. Laminating conditions were that a temperature of a substrate for a touch panel was 40° C., a temperature of a rubber roller (that is, a laminating temperature) was 110° C., a linear pressure was 3 N/cm, and a transportation speed was 2 m/min. Here, ITO is a film which is assumed as an electrode of a touch panel. The laminating property was good.

Next, without using an exposure mask, the obtained laminate C was exposed through the temporary support using a proximity type exposure machine [manufactured by Hitachi High-Tech Electronics Engineering Co., Ltd.] including an ultra-high pressure mercury lamp with an exposure amount of 100 mJ/cm² (i-rays). The temporary support was peeled off from the laminate after the entire surface exposure to obtain a sample after the exposure. Next, post-exposure was performed using a high-pressure mercury lamp. The exposure amount measured with a 365 nm illuminance meter was 375 mJ/cm². The post-exposed laminate was post-baked at 140° C. for 30 minutes in an oven to cure the photosensitive composition layer, thereby forming a cured film.

In this way, an ITO adhesiveness measuring sample having a laminated structure of “temporary support/cured film/refractive index-adjusting layer/ITO layer/substrate (glass)” was obtained.

A cross-cut test was performed on the ITO adhesiveness measuring sample according to the method of ASTM D3359-17. A portion peeled off from the copper substrate was confirmed, and in a case of being confirmed, an area was measured. Based on the measured values, the adhesiveness to the ITO substrate after exposure was evaluated according to the following evaluation standard.

In the following evaluation standard, “Area proportion of portion peeled off from substrate” is a value (unit: %) obtained by the following expression.

Area proportion of portion peeled off from copper substrate (unit: %)=(Portion peeled off from substrate)/[(Portion peeled off from substrate)+(Portion not peeled off from copper substrate)]×100

In the following evaluation standard, A indicates a case where the adhesiveness to the substrate was most excellent, and F indicates a case where the adhesiveness to the substrate was most deteriorated. In a case where the evaluation result was any one of A or B, it was determined that the evaluation result was within a practically acceptable range.

A: portion peeled off from the substrate was not confirmed.

B: area proportion of the portion peeled off from the substrate was less than 5%.

C: area proportion of the portion peeled off from the substrate was 5% or more.

(Yellowing)

A yellowing measuring sample having a laminated structure of “temporary support/cured film/refractive index-adjusting layer/substrate (glass)” was obtained in the same manner as the production of the ITO adhesiveness measuring sample, except that ITO-unlaminated glass was used instead of the ITO-laminated glass.

A UV-VIS spectrum of the yellowing measuring sample was measured, and an absorbance at 420 nm was measured to evaluate yellowing. In the following evaluation standard, A or B is preferable, and A is more preferable.

A: absorbance was less than 0.1.

B: absorbance was 0.1 or more and less than 0.2.

C: absorbance was 0.2 or more.

The results of the above-described evaluation tests are shown in Table 1.

TABLE 1

| | | Example | | | | | |
|---|---|---|---|---|---|---|---|
| Table 1 (1) | | 1 | 2 | 3 | 4 | 5 | 6 |
| Type of photosensitive composition | | A-1 | A-2 | A-3 | A-4 | A-5 | A-6 |
| Alkali-soluble resin | A-1 | 51.1 | 51.1 | 51.1 | 51.1 | 51.1 | 51.1 |
| | A-2 not having radically | | | | | | |
| | polymerizable group | | | | | | |
| | A-3 | | | | | | |
| | A-4 | | | | | | |
| | A-5 | | | | | | |
| | A-6 | | | | | | |
| | A-7 not having radically | | | | | | |
| | polymerizable group | | | | | | |
| Polymerizable compound | A-DCP (alicyclic structure) | 16.3 | 16.3 | 16.3 | 16.3 | 16.3 | 16.3 |
| | (bifunctional) | | | | | | |
| | A-NOD-N (bifunctional) | 2.8 | 2.8 | 2.8 | 2.8 | 2.8 | 2.8 |
| | DPHA (hexafunctional) | 8.2 | 8.2 | 8.2 | 8.2 | 8.2 | 8.2 |
| | TO-2349 (hepta- or hexafuctional) | 3 | 3 | 3 | 3 | 3 | 3 |
| | TMPT (trifuctional) | | | | | | |
| | DTMPT (tetrafuctional) | | | | | | |
| Specific polymerization | I-1 | 0.7 | | | | | |
| initiator | I-2 | | 0.7 | | | | |
| | I-3 | | | 0.7 | | | |
| | I-4 | | | | 0.7 | | |
| | I-5 | | | | | 0.7 | |
| | I-6 | | | | | | 0.7 |
| | I-7 | | | | | | |
| | I-8 | | | | | | |
| | I-9 | | | | | | |
| | I-10 | | | | | | |
| | I-11 | | | | | | |
| | II-1 | | | | | | |
| | II-2 | | | | | | |
| | II-3 | | | | | | |
| Other polymerization initiators | OXE-02 | 0.35 | 0.35 | 0.35 | 0.35 | 0.35 | 0.35 |
| | OXE-03 | | | | | | |
| | Omnirad-907 | | | | | | |
| Blocked isocyanate compound | First blocked | 2.5 | 2.5 | 2.5 | 2.5 | 2.5 | 2.5 |
| | isocyanate compound | | | | | | |
| | Second blocked | 12.5 | 12.5 | 12.5 | 12.5 | 12.5 | 12.5 |
| | isocyanate compound | | | | | | |
| Other components | N-phenylglycine | 0.5 | 0.5 | 0.5 | 0.5 | 0.5 | 0.5 |
| | Benzimidazole | 0.15 | 0.15 | 0.15 | 0.15 | 0.15 | 0.15 |
| | Isonicotinamide | 0.5 | 0.5 | 0.5 | 0.5 | 0.5 | 0.5 |
| | SMA EF-40 (manufactured | 1.2 | 1.2 | 1.2 | 1.2 | 1.2 | 1.2 |
| | by Cray Valley) | | | | | | |
| | MEGAFACE F551A (manufactured | 0.2 | 0.2 | 0.2 | 0.2 | 0.2 | 0.2 |
| | by DIC Corporation) | | | | | | |
| Total solid contents (part by mass) | | 100.0 | 100.0 | 100.0 | 100.0 | 100.0 | 100.0 |
| Evaluation result | Bending resistance | B | B | B | B | B | B |
| | Moisture permeability | A | A | A | A | A | A |
| | ITO adhesiveness | B | B | A | B | A | B |
| | Yellowing | A | A | A | A | A | A |

TABLE 2

| | | Example | | | | | | | |
|---|---|---|---|---|---|---|---|---|---|
| Table 1 (2) | | 7 | 8 | 9 | 10 | 11 | 12 | 13 | 14 |
| Type of photosensitive composition | | A-7 | A-8 | A-9 | A-10 | A-11 | A-12 | A-13 | A-14 |
| Alkali-soluble resin | A-1 | 51.1 | 51.1 | 51.1 | 51.1 | 51.1 | 51.1 | 51.1 | 51.1 |
| | A-2 not having radically | | | | | | | | |
| | polymerizable group | | | | | | | | |
| | A-3 | | | | | | | | |
| | A-4 | | | | | | | | |
| | A-5 | | | | | | | | |
| | A-6 | | | | | | | | |
| | A-7 not having radically | | | | | | | | |
| | polymerizable group | | | | | | | | |
| Polymerizable | A-DCP (alicyclic structure) | 16.3 | 16.3 | 16.3 | 16.3 | 16.3 | 16.3 | 16.3 | 16.3 |
| | (bifunctional) | | | | | | | | |
| compound | A-NOD-N (bifunctional) | 2.8 | 2.8 | 2.8 | 2.8 | 2.8 | 2.8 | 2.8 | 2.8 |
| | DPHA (hexafunctional) | 8.2 | 8.2 | 8.2 | 8.2 | 8.2 | 8.2 | 8.2 | 8.2 |
| | TO-2349 (hepta- or | 3 | 3 | 3 | 3 | 3 | 3 | 3 | 3 |
| | hexafuctional) | | | | | | | | |
| | TMPT (trifuctional) | | | | | | | | |
| | DTMPT (tetrafuctional) | | | | | | | | |
| Specific | I-1 | | | | | | | | |
| polymerization | I-2 | | | | | | | | |
| initiator | I-3 | | | | | | | | |
| | I-4 | | | | | | | | |
| | I-5 | | | | | | | | |
| | I-6 | | | | | | | | |
| | I-7 | 0.7 | | | | | | | |
| | I-8 | | 0.7 | | | | | | |
| | I-9 | | | 0.7 | | | | | |
| | I-10 | | | | 0.7 | | | | |
| | I-11 | | | | | 0.7 | | | |
| | II-1 | | | | | | 0.7 | | |
| | II-2 | | | | | | | 0.7 | |
| | II-3 | | | | | | | | 0.7 |
| Other | OXE-02 | 0.35 | 0.35 | 0.35 | 0.35 | 0.35 | 0.35 | 0.35 | 0.35 |
| polymerization | OXE-03 | | | | | | | | |
| initiators | Omnirad-907 | | | | | | | | |
| Blocked isocyanate | First blocked isocyanate | 2.5 | 2.5 | 2.5 | 2.5 | 2.5 | 2.5 | 2.5 | 2.5 |
| | compound | | | | | | | | |
| compound | Second blocked isocyanate | 12.5 | 12.5 | 12.5 | 12.5 | 12.5 | 12.5 | 12.5 | 12.5 |
| | compound | | | | | | | | |
| Other components | N-phenylglycine | 0.5 | 0.5 | 0.5 | 0.5 | 0.5 | 0.5 | 0.5 | 0.5 |
| | Benzimidazole | 0.15 | 0.15 | 0.15 | 0.15 | 0.15 | 0.15 | 0.15 | 0.15 |
| | Isonicotinamide | 0.5 | 0.5 | 0.5 | 0.5 | 0.5 | 0.5 | 0.5 | 0.5 |
| | SMA EF-40 (manufactured | 1.2 | 1.2 | 1.2 | 1.2 | 1.2 | 1.2 | 1.2 | 1.2 |
| | by Cray Valley) | | | | | | | | |
| | MEGAFACE F551A | 0.2 | 0.2 | 0.2 | 0.2 | 0.2 | 0.2 | 0.2 | 0.2 |
| | (manufactured by DIC | | | | | | | | |
| | Corporation) | | | | | | | | |
| Total solid contents (part by mass) | | 100.0 | 100.0 | 100.0 | 100.0 | 100.0 | 100.0 | 100.0 | 100.0 |
| Evaluation result | Bending resistance | B | B | B | B | A | B | B | B |
| | Moisture permeability | A | A | A | A | A | A | A | A |
| | ITO adhesiveness | A | A | A | A | A | A | A | A |
| | Yellowing | A | A | A | A | A | A | A | A |

TABLE 3

| | | Example | | | | | | |
|---|---|---|---|---|---|---|---|---|
| Table 1 (3) | | 15 | 16 | 17 | 18 | 19 | 20 | 21 |
| Type of photosensitive composition | | A-15 | A-16 | A-17 | A-18 | A-19 | A-20 | A-21 |
| Alkali-soluble resin | A-1 | 51.7 | 51.6 | 51.5 | 50.8 | 50.3 | 49.8 | 48.8 |
| | A-2 not having radically | | | | | | | |
| | polymerizable group | | | | | | | |
| | A-3 | | | | | | | |
| | A-4 | | | | | | | |
| | A-5 | | | | | | | |
| | A-6 | | | | | | | |
| | A-7 not having radically | | | | | | | |
| | polymerizable group | | | | | | | |
| Polymerizable | A-DCP (alicyclic structure) | 16.3 | 16.3 | 16.3 | 16.3 | 16.3 | 16.3 | 16.3 |
| | (bifunctional) | | | | | | | |
| compound | A-NOD-N (bifunctional) | 2.8 | 2.8 | 2.8 | 2.8 | 2.8 | 2.8 | 2.8 |
| | DPHA (hexafunctional) | 8.2 | 8.2 | 8.2 | 8.2 | 8.2 | 8.2 | 8.2 |
| | TO-2349 (hepta- or hexafuctional) | 3 | 3 | 3 | 3 | 3 | 3 | 3 |
| | TMPT (trifuctional) | | | | | | | |
| | DTMPT (tetrafuctional) | | | | | | | |
| Specific polymerization | I-1 | | | | | | | |
| initiator | I-2 | | | | | | | |
| | I-3 | | | | | | | |
| | I-4 | | | | | | | |
| | I-5 | | | | | | | |
| | I-6 | | | | | | | |
| | I-7 | | | | | | | |
| | I-8 | | | | | | | |
| | I-9 | | | | | | | |
| | I-10 | | | | | | | |
| | I-11 | 0.1 | 0.2 | 0.3 | 1 | 1.5 | 2 | 3 |
| | II-1 | | | | | | | |
| | II-2 | | | | | | | |
| | II-3 | | | | | | | |
| Other polymerization | OXE-02 | 0.35 | 0.35 | 0.35 | 0.35 | 0.35 | 0.35 | 0.35 |
| initiators | OXE-03 | | | | | | | |
| | Omnirad-907 | | | | | | | |
| Blocked isocyanate | First blocked isocyanate compound | 2.5 | 2.5 | 2.5 | 2.5 | 2.5 | 2.5 | 2.5 |
| compound | Second blocked isocyanate | 12.5 | 12.5 | 12.5 | 12.5 | 12.5 | 12.5 | 12.5 |
| | compound | | | | | | | |
| Other components | N-phenylglycine | 0.5 | 0.5 | 0.5 | 0.5 | 0.5 | 0.5 | 0.5 |
| | Benzimidazole | 0.15 | 0.15 | 0.15 | 0.15 | 0.15 | 0.15 | 0.15 |
| | [sonicotinamide | 0.5 | 0.5 | 0.5 | 0.5 | 0.5 | 0.5 | 0.5 |
| | SMA EF-40 (manufactured | 1.2 | 1.2 | 1.2 | 1.2 | 1.2 | 1.2 | 1.2 |
| | by Cray Valley) | | | | | | | |
| | MEGAFACE F551A (manufactured | 0.2 | 0.2 | 0.2 | 0.2 | 0.2 | 0.2 | 0.2 |
| | by DIC Corporation) | | | | | | | |
| Total solid contents (part by mass) | | 100.0 | 100.0 | 100.0 | 100.0 | 100.0 | 100.0 | 100.0 |
| Evaluation result | Bending resistance | A | A | A | A | B | B | B |
| | Moisture permeability | B | B | A | A | A | A | A |
| | ITO adhesiveness | B | A | A | A | A | A | B |
| | Yellowing | A | A | A | A | A | B | B |

TABLE 4

| | | Example | | | | | |
|---|---|---|---|---|---|---|---|
| Table 1 (4) | | 22 | 23 | 24 | 25 | 26 | 27 |
| Type of photosensitive composition | | A-22 | A-23 | A-24 | A-25 | A-26 | A-27 |
| Alkali-soluble resin | A-1 | | | | | | |
| | A-2 not having | 51.1 | | | | | |
| | radically polymerizable group | | | | | | |
| | A-3 | | 51.1 | | | | |
| | A-4 | | | 51.1 | | | |
| | A-5 | | | | 51.1 | | |
| | A-6 | | | | | 51.1 | |
| | A-7 not having radically | | | | | | 51.1 |
| | polymerizable group | | | | | | |
| Polymerizable | A-DCP (alicyclic structure) | 16.3 | 16.3 | 16.3 | 16.3 | 16.3 | 16.3 |
| compound | (bifunctional) | | | | | | |
| | A-NOD-N (bifunctional) | 2.8 | 2.8 | 2.8 | 2.8 | 2.8 | 2.8 |
| | DPHA (hexafunctional) | 8.2 | 8.2 | 8.2 | 8.2 | 8.2 | 8.2 |
| | TO-2349 (hepta- or hexafuctional) | 3 | 3 | 3 | 3 | 3 | 3 |
| | TMPT (trifuctional) | | | | | | |
| | DTMPT (tetrafuctional) | | | | | | |
| Specific polymerization | I-1 | | | | | | |
| initiator | I-2 | | | | | | |
| | I-3 | | | | | | |
| | I-4 | | | | | | |
| | I-5 | | | | | | |
| | I-6 | | | | | | |
| | I-7 | | | | | | |
| | I-8 | | | | | | |
| | I-9 | | | | | | |
| | I-10 | | | | | | |
| | I-11 | 0.7 | 0.7 | 0.7 | 0.7 | 0.7 | 0.7 |
| | II-1 | | | | | | |
| | II-2 | | | | | | |
| | II-3 | | | | | | |
| Other polymerization | OXE-02 | 0.35 | 0.35 | 0.35 | 0.35 | 0.35 | 0.35 |
| initiators | OXE-03 | | | | | | |
| | Omnirad-907 | | | | | | |
| Blocked isocyanate | First blocked isocyanate compound | 2.5 | 2.5 | 2.5 | 2.5 | 2.5 | 2.5 |
| compound | Second blocked isocyanate compound | 12.5 | 12.5 | 12.5 | 12.5 | 12.5 | 12.5 |
| Other components | N-phenylglycine | 0.5 | 0.5 | 0.5 | 0.5 | 0.5 | 0.5 |
| | Benzimidazole | 0.15 | 0.15 | 0.15 | 0.15 | 0.15 | 0.15 |
| | [sonicotinamide | 0.5 | 0.5 | 0.5 | 0.5 | 0.5 | 0.5 |
| | SMA EF-40 | 1.2 | 1.2 | 1.2 | 1.2 | 1.2 | 1.2 |
| | (manufactured by Cray Valley) | | | | | | |
| | MEGAFACE F551A | 0.2 | 0.2 | 0.2 | 0.2 | 0.2 | 0.2 |
| | (manufactured by DIC Corporation) | | | | | | |
| Total solid contents (part by mass) | | 100.0 | 100.0 | 100.0 | 100.0 | 100.0 | 100.0 |
| Evaluation result | Bending resistance | A | A | A | A | A | A |
| | Moisture permeability | B | A | A | A | A | B |
| | ITO adhesiveness | A | A | A | A | A | A |
| | Yellowing | A | A | A | A | A | A |

TABLE 5

| | | Example | | | | |
|---|---|---|---|---|---|---|
| Table 1 (5) | | 28 | 29 | 30 | 31 | 32 |
| Type of photosensitive composition | | A-28 | A-29 | A-30 | A-31 | A-32 |
| Alkali-soluble resin | A-1 | 51.1 | 51.1 | 51.1 | 51.1 | 51.1 |
| | A-2 not having radically | | | | | |
| | polymerizable group | | | | | |
| | A-3 | | | | | |
| | A-4 | | | | | |
| | A-5 | | | | | |
| | A-6 | | | | | |
| | A-7 not having radically | | | | | |
| | polymerizable group | | | | | |
| Polymerizable | A-DCP (alicyclic structure) | | | | 16.3 | 16.3 |
| compound | (bifunctional) | | | | | |
| | A-NOD-N (bifunctional) | | 19.1 | | 2.8 | 2.8 |
| | DPHA (hexafunctional) | 27.3 | 8.2 | 8.2 | 8.2 | |
| | TO-2349 (hepta- or hexafuctional) | 3 | 3 | 3 | 3 | |
| | TMPT (trifuctional) | | | 19.1 | | 7.1 |
| | DTMPT (tetrafuctional) | | | | | 4.1 |
| Specific | 1-1 | | | | | |
| polymerization | 1-2 | | | | | |
| initiator | 1-3 | | | | | |
| | 1-4 | | | | | |
| | 1-5 | | | | | |
| | 1-6 | | | | | |
| | 1-7 | | | | | |
| | 1-8 | | | | | |
| | 1-9 | | | | | |
| | 1-10 | | | | | |
| | 1-11 | 0.7 | 0.7 | 0.7 | 0.7 | 0.7 |
| | 11 1 | | | | | |
| | 11 2 | | | | | |
| | 11 3 | | | | | |
| Other polymerization | OXE-02 | 0.35 | 0.35 | 0.35 | | 0.35 |
| initiators | OXE-03 | | | | 0.35 | |
| | Omnirad-907 | | | | | |
| Blocked isocyanate | First blocked isocyanate compound | 2.5 | 2.5 | 2.5 | 2.5 | 2.5 |
| compound | Second blocked isocyanate compound | 12.5 | 12.5 | 12.5 | 12.5 | 12.5 |
| Other components | N-phenylglycine | 0.5 | 0.5 | 0.5 | 0.5 | 0.5 |
| | Benzimidazole | 0.15 | 0.15 | 0.15 | 0.15 | 0.15 |
| | Isonicotinamide | 0.5 | 0.5 | 0.5 | 0.5 | 0.5 |
| | SMA EF-40 | 1.2 | 1.2 | 1.2 | 1.2 | 1.2 |
| | (manufactured by Cray Valley) | | | | | |
| | MEGAFACE F551A | 0.2 | 0.2 | 0.2 | 0.2 | 0.2 |
| | (manufactured by DIC Corporation) | | | | | |
| Total solid contents (part by mass) | | 100.0 | 100.0 | 100.0 | 100.0 | 100.0 |
| Evaluation result | Bending resistance | B | A | B | A | A |
| | Moisture permeability | B | B | B | A | A |
| | ITO adhesiveness | A | A | A | A | B |
| | Yellowing | A | A | A | A | A |

TABLE 6

| | | Example | | | | | |
|---|---|---|---|---|---|---|---|
| Table 1 (6) | | 33 | 34 | 35 | 36 | 37 | 38 |
| Type of photosensitive composition | | A-33 | A-34 | A-35 | A-36 | A-37 | A-3 8 |
| Alkali-soluble resin | A-1 | 43.5 | 57.5 | | | | 53.6 |
| | A-2 not having radically | | | | | | |
| | polymerizable group | | | | | | |
| | A-3 | | | | | | |
| | A-4 | | | 51.1 | | | |
| | A-5 | | | | 51.1 | | |
| | A-6 | | | | | 51.1 | |
| | A-7 not having radically | | | | | | |
| | polymerizable group | | | | | | |
| Polymerizable compound | A-DCP (alicyclic structure) | 16.3 | 13.3 | 16.3 | 16.3 | 16.3 | 16.3 |
| | (bifunctional) | | | | | | |
| | A-NOD-N (bifunctional) | 6.6 | 2.6 | 2.8 | 2.8 | 2.8 | 2.8 |
| | DPHA (hexafunctional) | 12 | 5 | 8.2 | 8.2 | 8.2 | 82 |
| | TO-2349 (hepta- or hexafuctional) | 3 | 3 | 3 | 3 | 3 | 3 |
| | TMPT (trifuctional) | | | | | | |
| | DTMPT (tetrafuctional) | | | | | | |
| Specific polymerization | 1-1 | | | | | | |
| initiator | 1-2 | | | | | | |
| | 1-3 | | | | | | |
| | 1-4 | | | 0.7 | | | |
| | 1-5 | | | | 0.7 | | |
| | 1-6 | | | | | | |
| | 1-7 | | | | | 0.7 | |
| | 1-8 | | | | | | |
| | 1-9 | | | | | | |
| | 1-10 | | | | | | |
| | 1-11 | 0.7 | 0.7 | | | | 0.7 |
| | 11-1 | | | | | | |
| | 11-2 | | | | | | |
| | 11-3 | | | | | | |
| Other polymerization | OXE-02 | 0.35 | 0.35 | 0.35 | 0.35 | 0.35 | 0.35 |
| initiators | OXE-03 | | | | | | |
| | Omnirad-907 | | | | | | |
| Blocked isocyanate | First blocked isocyanate compound | 2.5 | 2.5 | 2.5 | 2.5 | 2.5 | |
| compound | Second blocked isocyanate compound | 12.5 | 12.5 | 12.5 | 12.5 | 12.5 | 12.5 |
| Other components | N-phenylglycine | 0.5 | 0.5 | 0.5 | 0.5 | 0.5 | 0.5 |
| | Benzimidazole | 0.15 | 0.15 | 0.15 | 0.15 | 0.15 | 0.15 |
| | Isonicotinamide | 0.5 | 0.5 | 0.5 | 0.5 | 0.5 | 0.5 |
| | SMA EF-40 | 1.2 | 1.2 | 1.2 | 1.2 | 1.2 | 1.2 |
| | (manufactured by Cray Valley) | | | | | | |
| | MEGAFACE F551A | 0.2 | 0.2 | 0.2 | 0.2 | 0.2 | 0.2 |
| | (manufactured by DIC Corporation) | | | | | | |
| Total solid contents (part by mass) | | 100.0 | 100.0 | 100.0 | 100.0 | 100.0 | 100.0 |
| Evaluation result | Bending resistance | A | A | B | B | B | B |
| | Moisture permeability | A | A | A | A | A | A |
| | ITO adhesiveness | A | A | A | A | A | A |
| | Yellowing | A | A | A | A | A | A |

TABLE 7

| | | Example | | |
|---|---|---|---|---|
| Table 1 (7) | | 39 | 40 | 41 |
| Type of photosensitive composition | | A-39 | A-40 | A-41 |
| Alkali- | A-1 | 51.1 | 51.1 | 51.1 |
| soluble | A-2 not having radically | | | |
| resin | polymerizable group | | | |
| | A-3 | | | |
| | A-4 | | | |
| | A-5 | | | |
| | A-6 | | | |
| | A-7 not having radically | | | |
| | polymerizable group | | | |
| Polymerizable | A-DCP (alicyclic structure) | 16.3 | 16.3 | 16.3 |
| compound | (bifunctional) | | | |
| | A-NOD-N (bifunctional) | 2.8 | 2.8 | 2.8 |
| | DPHA (hexafunctional) | 8 | 8 | 8.7 |
| | TO-2349 (hepta- or | 3 | 3 | 3 |
| | hexafuctional) | | | |
| | TMPT (trifuctional) | | | |
| | DTMPT (tetrafuctional) | | | |
| Specific | I-1 | | | |
| polymerization | I-2 | | | |
| initiator | I-3 | | | |
| | I-4 | | | |
| | I-5 | | 1.2 | |
| | I-6 | | | |
| | I-7 | | | |
| | I-8 | | | |
| | I-9 | | | |
| | I-10 | | | |
| | I-11 | 1.2 | | 1.2 |
| | II-1 | | | |
| | II-2 | | | |
| | II-3 | | | |
| Other | OXE-02 | | | |
| polymerization | OXE-03 | | | |
| initiators | Ornnirad-907 | | | |
| Blocked | First blocked isocyanate | 2.5 | 2.5 | 2.5 |
| isocyanate | compound | | | |
| compound | Second blocked isocyanate | 12.5 | 12.5 | 12.5 |
| | compound | | | |
| Other | N-phenylglycine | 0.5 | 0.5 | 0.5 |
| components | Benzimidazole | 0.15 | 0.15 | |
| | Isonicotinamide | 0.5 | 0.5 | |
| | SMA EF-40 (manufactured | 1.2 | 1.2 | 1.2 |
| | by Cray Valley) | | | |
| | MEGAFACE F551A | 0.2 | 0.2 | 0.2 |
| | (manufactured by | | | |
| | DIC Corporation) | | | |
| Total solid contents (part by mass) | | 100.0 | 100.0 | 100.0 |
| Evaluation | Bending resistance | A | B | A |
| result | Moisture permeability | B | B | B |
| | ITO adhesiveness | A | A | A |
| | Yellowing | A | A | A |

TABLE 8

| | | Comparative Example | | | |
|---|---|---|---|---|---|
| Table 1 (8) | | 1 | 2 | 3 | 4 |
| Type of photosensitive composition | | B-1 | B-2 | B-3 | B-4 |
| Alkali- | A-1 | | 51.1 | 51.75 | 50.1 |
| soluble | A-2 not having radically | 51.1 | | | |
| resin | polymerizable group | | | | |
| | A-3 | | | | |
| | A-4 | | | | |
| | A-5 | | | | |
| | A-6 | | | | |
| | A-7 not having radically | | | | |
| | polymerizable group | | | | |
| Polymerizable | A-DCP (alicyclic structure) | 16.3 | 16.3 | 16.3 | 15.3 |
| compound | (bifunctional) | | | | |
| | A-NOD-N (bifunctional) | 2.8 | 2.8 | 2.8 | 2.5 |
| | DPHA (hexafunctional) | 8.2 | 8.2 | 8.2 | 7.2 |
| | TO-2349 (hepta- or | 3 | 3 | 3 | 3 |
| | hexafuctional) | | | | |
| | TMPT (trifuctional) | | | | |
| | DTMPT (tetrafuctional) | | | | |
| Specific | I-1 | | | | |
| polymerization | I-2 | | | | |
| initiator | I-3 | | | | |
| | I-4 | | | | |
| | I-5 | | | | |
| | I-6 | | | | |
| | I-7 | | | | |
| | I-8 | | | | |
| | I-9 | | | | |
| | I-10 | | | | |
| | I-11 | | | 0.05 | 4 |
| | II-1 | | | | |
| | II-2 | | | | |
| | II-3 | | | | |
| Other | OXE-02 | 0.35 | 0.35 | 0.35 | 0.35 |
| polymerization | OXE-03 | | | | |
| initiators | Omnirad-907 | 0.7 | 0.7 | | |
| Blocked | First blocked isocyanate | 2.5 | 2.5 | 2.5 | 2.5 |
| isocyanate | compound | | | | |
| compound | Second blocked isocyanate | 12.5 | 12.5 | 12.5 | 12.5 |
| | compound | | | | |
| Other | N-phenylglycine | 0.5 | 0.5 | 0.5 | 0.5 |
| components | Benzimidazole | 0.15 | 0.15 | 0.15 | 0.15 |
| | Isonicotinamide | 0.5 | 0.5 | 0.5 | 0.5 |
| | SMA EF-40 (manufactured | 1.2 | 1.2 | 1.2 | 1.2 |
| | by Cray Valley) | | | | |
| | MEGAFACE F551A | 0.2 | 0.2 | 0.2 | 0.2 |
| | (manufactured by | | | | |
| | DIC Corporation) | | | | |
| Total solid contents (part by mass) | | 100.0 | 100.0 | 100.0 | 100.0 |
| Evaluation | Bending resistance | C | C | B | C |
| result | Moisture permeability | Reference | B | C | B |
| | ITO adhesiveness | C | B | B | B |
| | Yellowing | C | B | A | C |

As shown in Table 1, in a case of having a temporary support and a photosensitive composition layer disposed on the temporary support, in which the photosensitive composition layer included an alkali-soluble resin, a polymerizable compound, and a specific polymerization initiator, and a content of the specific polymerization initiator in the photosensitive composition layer was 0.1% to 3.0% by mass, it was shown that a cured film having excellent bending resistance and capable of suppressing yellowing could be formed (Examples).

In the comparison of Examples 1 to 14, in a case where the specific polymerization initiator was a polymerization initiator represented by Formula I, X¹ in Formula I was a group represented by R¹², and R¹² was an aryl group which may have a substituent, it was shown that the bending resistance of the cured film was more excellent.

In a case where the specific polymerization initiator is the polymerization initiator represented by Formula I (Examples 1 to 11), it was shown that, in a case of using a specific polymerization initiator in which X¹ in Formula I was a group having an aromatic ring (Examples 3, 5, and 7 to 11), the ITO adhesiveness was more excellent.

From the comparison of Example 11 and Examples 15 to 21, in a case where the content of the specific polymerization initiator in the photosensitive composition was 0.2% to 2% by mass (Examples 11 and 16 to 20), it was shown that the ITO adhesiveness was more excellent.

From the comparison of Example 11 and Examples 15 to 21, in a case where the content of the specific polymerization initiator in the photosensitive composition was 0.3% by mass or more (Examples 11 and 17 to 21), it was shown that the moisture permeability could be further suppressed.

From the comparison of Example 11 and Examples 15 to 21, in a case where the content of the specific polymerization initiator in the photosensitive composition was 1.5% by mass or less (Examples 11 and 15 to 19), it was shown that the yellowing could be further suppressed.

From the comparison of Example 11 and Examples 15 to 21, in a case where the content of the specific polymerization initiator in the photosensitive composition was 1.0% by mass or less (Examples 11 and 15 to 18), it was shown that the bending resistance was more excellent.

From the comparison of Example 11 and Examples 22 to 27, in a case where the alkali-soluble resin included a structural unit having a radically polymerizable group (Examples 11 and 23 to 26), it was shown that the moisture permeability could be further suppressed.

From the comparison of Example 11 and Examples 26 to 28, in a case where the polymerizable compound included a (meth)acrylate compound that had an aliphatic ring which may include an oxygen atom or a nitrogen atom in the ring and had two or more ethylenically unsaturated groups in one molecule (Example 11), it was shown that the bending resistance was more excellent.

From the comparison of Example 31 and Example 32, in a case where the polymerizable compound included a (meth)acrylate compound having two ethylenically unsaturated groups in one molecule, it was shown that, in a case where the polymerizable compound further included a (meth)acrylate compound having five or six ethylenically unsaturated groups in one molecule, it was shown that the moisture permeability could be further suppressed and the ITO adhesiveness was also more excellent.

From the comparison of Examples 28 to 32, in a case where the polymerizable compound included the (meth)acrylate compound having two ethylenically unsaturated groups in one molecule and a (meth)acrylate compound having three to six ethylenically unsaturated groups in one molecule (Examples 29, 31, and 32), it was shown that at least one of bending resistance or moisture permeation suppression was more excellent.

From the comparison of Example 11 and Example 38, in a case of including a first blocked isocyanate compound (Example 11), it was shown that the bending resistance was more excellent.

As shown in Table 1, in a case where the content of the specific polymerization initiator in the photosensitive composition was outside the range of 0.1% to 3.0% by mass, it was shown that at least one of bending resistance or yellowing of the obtained cured film was deteriorated (Comparative Examples 1 to 4).

<Production of Touch Panel>

A substrate in which an ITO transparent electrode pattern and copper lead wire were formed on a polyimide transparent film was prepared.

By performing the same operation as in the above-described evaluation of bending resistance, the protective film of the produced transfer film of each example was peeled off, and the ITO transparent electrode pattern and the copper lead wire were laminated at the position covered by the transfer film. The laminating was performed using a vacuum laminator manufactured by MCK under conditions of a cycloolefin transparent film temperature: 40° C., a rubber roller temperature: 100° C., a linear pressure: 3 N/cm, and a transportation speed: 2 m/min.

Thereafter, using a proximity type exposure machine (manufactured by Hitachi High-Tech Electronics Engineering Co., Ltd.) having an ultra-high pressure mercury lamp, a surface of an exposure mask (quartz exposure mask having a pattern for forming an overcoat) and the temporary support were closely attached, and the laminate was exposed in a patterned shape with an exposure amount of 100 mJ/cm² (i-rays) through the temporary support.

After peeling off the temporary support, development treatment was performed at 26° C. in a 1% sodium carbonate aqueous solution for 65 seconds to form a cured film pattern.

Thereafter, an ultrapure water was sprayed onto the developed transparent film substrate from an ultrahigh pressure washing nozzle. Subsequently, air was blown to remove moisture on the transparent film substrate, and post-exposure was performed using a high-pressure mercury lamp. The exposure amount measured with a 365 nm illuminance meter was 1000 mJ/cm². Thereafter, post-baking treatment was performed at 180° C. for 30 minutes to form a transparent laminate in which the ITO transparent electrode pattern, the copper lead wire, the refractive index-adjusting layer, and the cured film pattern were laminated in this order on the transparent film substrate.

Using the produced transparent laminate, a touch panel was produced by a known method. The produced touch panel was attached to a liquid crystal display element produced by a method described in paragraphs 0097 to 0119 of JP2009-47936A, thereby producing a liquid crystal display device equipped with a touch panel.

It was confirmed that the liquid crystal display device equipped with a touch panel had excellent display properties and the touch panel operated without problems.

### Explanation of References

102: bending resistance evaluation sample
102A: bending resistance evaluation sample bent at 180°
104: weight
106: metal rod
D: reciprocating direction
d: diameter of metal rod 106

What is claimed is:

1. A transfer film comprising:
a temporary support; and
a photosensitive composition layer disposed on the temporary support,
wherein the photosensitive composition layer includes an alkali-soluble resin, a polymerizable compound, and a polymerization initiator represented by Formula I or Formula II, and
a content of the polymerization initiator is 0.1% to 3.0% by mass with respect to a total mass of the photosensitive composition layer, 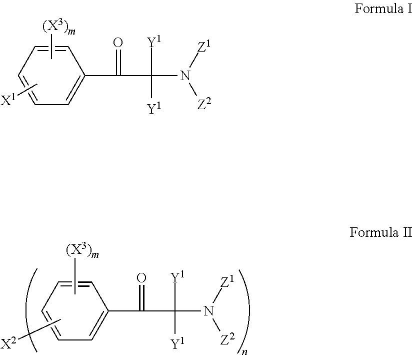
in Formula I, X¹ represents a group represented by —S—R¹¹ or a group represented by —R¹², R¹¹ and R¹² each independently represent a monovalent organic group having 2 or more carbon atoms,
in Formula II, X² represents an n-valent linking group,
in Formula I and Formula II, Y¹ and Y² each independently represent an alkyl group which may have a substituent or an aryl group which may have a substituent,
in Formula I and Formula II, Z¹ and Z² each independently represent an alkyl group which may have a substituent or an aryl group which may have a substituent, here, in a case where Z¹ and Z² are the alkyl group which may have a substituent, Z¹ and Z² may be linked to each other to form a ring,
in Formula I and Formula II, X³ represents a monovalent substituent,
in Formula I and Formula II, m represents an integer of 0 to 3, in a case where m is 2 or more, a plurality of X³'s may be the same or different from each other, and
in Formula II, n is 2 or 3.

2. The transfer film according to claim 1,
wherein X¹ in Formula I is a group having an aromatic ring.

3. The transfer film according to claim 1,
wherein the photosensitive composition layer further includes a polymerization initiator other than the polymerization initiator represented by Formula I and the polymerization initiator represented by Formula II.

4. The transfer film according to claim 3,
wherein, in the photosensitive composition layer, a mass ratio of a total content of the polymerization initiator represented by Formula I and the polymerization initiator represented by Formula II to a content of the polymerization initiator other than the polymerization initiator represented by Formula I and the polymerization initiator represented by Formula II is 0.5 to 10.

5. The transfer film according to claim 1,
wherein the polymerizable compound includes a (meth)acrylate compound that has an aliphatic ring which may include an oxygen atom or a nitrogen atom in the ring and has two or more ethylenically unsaturated groups in one molecule.

6. The transfer film according to claim 1,
wherein the polymerizable compound includes a (meth)acrylate compound having two ethylenically unsaturated groups in one molecule and a (meth)acrylate compound having three to six ethylenically unsaturated groups in one molecule.

7. The transfer film according to claim 1,
wherein the alkali-soluble resin includes at least one structural unit of a structural unit having an aromatic ring or a structural unit having an aliphatic ring.

8. The transfer film according to claim 2,
wherein the alkali-soluble resin includes a structural unit having an aliphatic ring and a structural unit having an acid group, and
the structural unit having an acid group is represented by Formula (3).

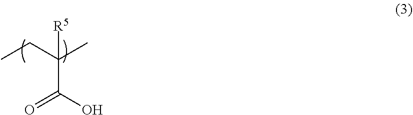

9. The transfer film according to claim 2,
wherein the alkali-soluble resin includes a structural unit having an aromatic ring and a structural unit having an acid group, and
the structural unit having an acid group is represented by Formula (3).

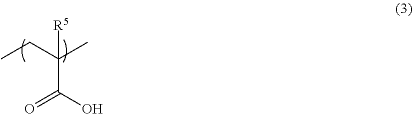

10. The transfer film according to claim 2,
wherein the alkali-soluble resin includes a structural unit having a radically polymerizable group.

11. The transfer film according to claim 1,
wherein the photosensitive composition layer further includes a blocked isocyanate compound.

12. The transfer film according to claim 1, further comprising:
a refractive index-adjusting layer,
wherein the refractive index-adjusting layer is disposed in contact with the photosensitive composition layer, and
a refractive index of the refractive index-adjusting layer is 1.60 or more.

13. The transfer film according to claim 1,
wherein the photosensitive composition layer is used for forming a touch panel electrode protective film.

14. A method for producing a laminate, comprising:
an affixing step of bringing the photosensitive composition layer on the temporary support of the transfer film according to claim 1 into contact with a substrate having a conductive layer to affix the photosensitive composition layer to the substrate and obtain a photosensitive composition layer-attached substrate having the substrate, the conductive layer, the photosensitive composition layer, and the temporary support in this order;
an exposing step of exposing the photosensitive composition layer in a patterned manner; and
a developing step of developing the exposed photosensitive composition layer to form a pattern,
wherein the producing method further includes, between the affixing step and the exposing step or between the exposing step and the developing step, a peeling step of peeling the temporary support from the substrate with a photosensitive composition layer.

15. The transfer film according to claim 2,
wherein the photosensitive composition layer further includes a polymerization initiator other than the polymerization initiator represented by Formula I and the polymerization initiator represented by Formula II.

16. The transfer film according to claim 2,
wherein the polymerizable compound includes a (meth)acrylate compound that has an aliphatic ring which may include an oxygen atom or a nitrogen atom in the ring and has two or more ethylenically unsaturated groups in one molecule.

17. The transfer film according to claim 2,
wherein the polymerizable compound includes a (meth)acrylate compound having two ethylenically unsaturated groups in one molecule and a (meth)acrylate compound having three to six ethylenically unsaturated groups in one molecule.

18. The transfer film according to claim 2,
wherein the alkali-soluble resin includes at least one structural unit of a structural unit having an aromatic ring or a structural unit having an aliphatic ring.

19. The transfer film according to claim 1,
wherein the alkali-soluble resin includes a structural unit having a radically polymerizable group.

20. The transfer film according to claim 2,
wherein the photosensitive composition layer further includes a blocked isocyanate compound.
